(19) United States
(12) Patent Application Publication
(10) Pub. No.: US 2013/0015871 A1
(43) Pub. Date: Jan. 17, 2013

(54) SYSTEMS, DEVICES, AND METHODS FOR TWO-SIDED TESTING OF ELECTRONIC DEVICES

(71) Applicants: Tim Cleary, Portland, OR (US); Peter Hanaway, Portland, OR (US); Eric Strid, Portland, OR (US); David Leslie, Sherwood, OR (US); Eric Hill, Portland, OR (US); Ken Smith, Beaverton, OR (US); K. Reed Gleason, Portland, OR (US)

(72) Inventors: Tim Cleary, Portland, OR (US); Peter Hanaway, Portland, OR (US); Eric Strid, Portland, OR (US); David Leslie, Sherwood, OR (US); Eric Hill, Portland, OR (US); Ken Smith, Beaverton, OR (US); K. Reed Gleason, Portland, OR (US)

(73) Assignee: Cascade Microtech, Inc., Beaverton, OR (US)

(21) Appl. No.: 13/542,337

(22) Filed: Jul. 5, 2012

Related U.S. Application Data
(60) Provisional application No. 61/506,424, filed on Jul. 11, 2011.

(51) Int. Cl. G01R 31/28

(52) U.S. Cl. 324/754.03

(57) ABSTRACT

Systems, devices, and methods for two-sided testing of electronic devices. These systems, devices, and methods may include the use of a test fixture that is configured to electrically connect a back side electrical pad of a device under test with an auxiliary pad that faces in a different direction than the back side electrical pad. Additionally or alternatively, these systems, devices, and methods also may include the use of a probe head that is configured to form an electrical connection with both the auxiliary pad and a front side electrical pad of the device under test. The systems, devices, and methods also may include providing a test signal to the device under test, receiving a resultant signal from the device under test, and/or analyzing the resultant signal.

### RELATED APPLICATION

This application claims priority to U.S. Provisional Patent Application No. 61/506,424, which was filed on Jul. 11, 2011, and the complete disclosure of which is hereby incorporated by reference.

### FIELD OF THE DISCLOSURE

The present disclosure is directed generally to systems, devices, and methods for two-sided testing of electronic devices.

### BACKGROUND OF THE DISCLOSURE

The trend in electronic device production, particularly in integrated circuit technology, has been toward fabricating larger numbers of discrete circuit elements with higher operating frequencies and smaller geometries on a single substrate, or wafer. After fabrication, the wafer is singulated, cut, or otherwise divided into a number of rectangular-shaped chips, or die, where each die presents a rectangular or other regular arrangement of bond, or contact, pads through which connections are made for inputs to and/or outputs from one or more electrical circuits that may be present on the die.

Traditionally, testing of the circuits formed on the wafer is performed while the die are still joined together on the wafer. One typical procedure is to support the wafer on a flat stage, or chuck, and to move the wafer in X, Y, and Z directions relative to a probe head of a probing assembly so that contacts on the probe head move relative to the surface of the wafer for consecutive engagement with the contact pads of one or more of a plurality of die on the wafer. Respective signal, power, and ground conductors that interconnect the test instrumentation with the contacts on the probe head enable circuits on the wafer to be sequentially connected to the instrumentation and tested. However, these traditional testing methods are only effective in testing bond, or contact, pads that are present on a single side of the wafer, i.e., a quasi 2-dimensional structure.

However, as integrated circuit operating frequencies continue to increase, and as device, or feature, geometries continue to decrease, integrated circuit manufactures have begun to explore architectures that may include the combination, or stacking, of multiple die in layers and/or side-by-side to form a stacked device, which includes a 2.5-dimensional and/or 3-dimensional integrated circuit structure, and which also may be referred to as a stacked semiconductor device and/or a composite semiconductor device. As used herein, a 2.5-dimensional integrated circuit structure may refer to a structure in which a plurality of individual die are stacked together on, and interconnected by, a common interposer substrate, while a 3-dimensional integrated circuit structure may refer to a structure in which a plurality of individual die are stacked on top of one another to form a layered, or composite, integrated circuit structure.

Such architectures may have several advantages over current 2-dimensional architectures; however, they also present unique manufacturing and/or testing challenges. As an illustrative, non-exclusive example, interposers and/or individual die that are utilized in 2.5-dimensional and/or 3-dimensional integrated circuit architectures may include bond pads on two sides of the die (nominally the top and bottom, which also may be referred to as the front and back sides and/or as first and second opposed sides). Thus, testing methodologies that may make simultaneous electrical contact with both sides of the die, or other electronic device to be tested, may be desired. In addition, a thickness and/or rigidity of these interposers and/or die may be significantly less than that of those utilized in 2-dimensional architectures. Thus, testing methodologies that may make electrical contact between the probe head and the die without significant deformation of and/or damage to the die also may be desired.

### SUMMARY OF THE DISCLOSURE

Systems, devices, and methods for two-sided testing of electronic devices. These systems, devices, and methods may include the use of a test fixture that is configured to electrically connect a back side electrical pad of a device under test with an auxiliary pad. Additionally or alternatively, these systems, devices, and methods also may include the use of a probe head that is configured to form an electrical connection with both the auxiliary pad and a front side electrical pad of the device under test. The systems, devices, and methods also may include providing a test signal to the device under test, receiving a resultant signal from the device under test, and/or analyzing the resultant signal.

In some embodiments, the auxiliary pad may face in a different direction than the back side electrical pad. In some embodiments, the auxiliary pad may face in the same, or in at least substantially the same, direction as the front side electrical pad. In some embodiments, the auxiliary pad may form a portion of the test fixture. In some embodiments, the auxiliary pad may form a portion of the device under test.

In some embodiments, the systems, devices, and/or methods may include electrically contacting the front side electrical pad and the auxiliary pad from the same direction. In some embodiments, the contacting may be from and/or in the direction of the front side of the device under test. In some embodiments, the probe head may electrically contact both the front side electrical pads and the auxiliary pads from the front side of the device under test. In some embodiments, the probe head may include at least a first probe head region that is configured to form an electrical connection with the front side electrical pad and a second probe head region that is configured to form an electrical connection with the auxiliary pad.

### BRIEF DESCRIPTION OF THE DRAWINGS

FIG. 1 is a schematic representation of illustrative, non-exclusive examples of a test assembly according to the present disclosure.

FIG. 2 is a less schematic but still illustrative, non-exclusive example of a test assembly according to the present disclosure.

FIG. 3 is provides less schematic but still illustrative, non-exclusive examples of a test assembly according to the present disclosure, with the illustrated test assembly including a test fixture with an interposer that routes a back side electrical pad to an auxiliary pad that is accessible from a front side of the device under test.

FIG. 4 provides less schematic but still illustrative, non-exclusive examples of a test assembly according to the present disclosure, with the illustrated test assembly including a test fixture with an interposer that routes a back side electrical pad to a front side electrical pad.

FIG. 5 provides less schematic but still illustrative, non-exclusive examples of a test assembly according to the present disclosure, with the illustrated test assembly including a test fixture with an interposer that routes a back side electrical pad of a first device under test to a front side electrical pad of a second device under test.

FIG. 6 is a schematic representation of illustrative, non-exclusive examples of a test fixture that includes electrical contacts that are in complementary locations to the corresponding locations of back side electrical pads of the device under test.

FIG. 7 is a schematic representation of illustrative, non-exclusive examples of a test fixture that includes a periodically spaced array of electrical contacts.

FIG. 8 is a schematic representation of illustrative, non-exclusive examples of a two-zone probe head according to the present disclosure.

FIG. 9 is a schematic representation of illustrative, non-exclusive examples of a test assembly that includes a high compliance contacting structure and a low compliance contacting structure.

FIG. 10 is schematic representation of additional illustrative, non-exclusive examples of a test assembly that includes a high compliance contacting structure and a low compliance contacting structure.

FIG. 11 is a flowchart depicting illustrative, non-exclusive examples of methods according to the present disclosure of probing a device under test.

FIG. 12 is a flowchart depicting illustrative, non-exclusive examples of methods according to the present disclosure of testing a device under test.

FIG. 13 is a flowchart depicting illustrative, non-exclusive examples of methods according to the present disclosure of electrically contacting a device under test.

### DETAILED DESCRIPTION AND BEST MODE OF THE DISCLOSURE

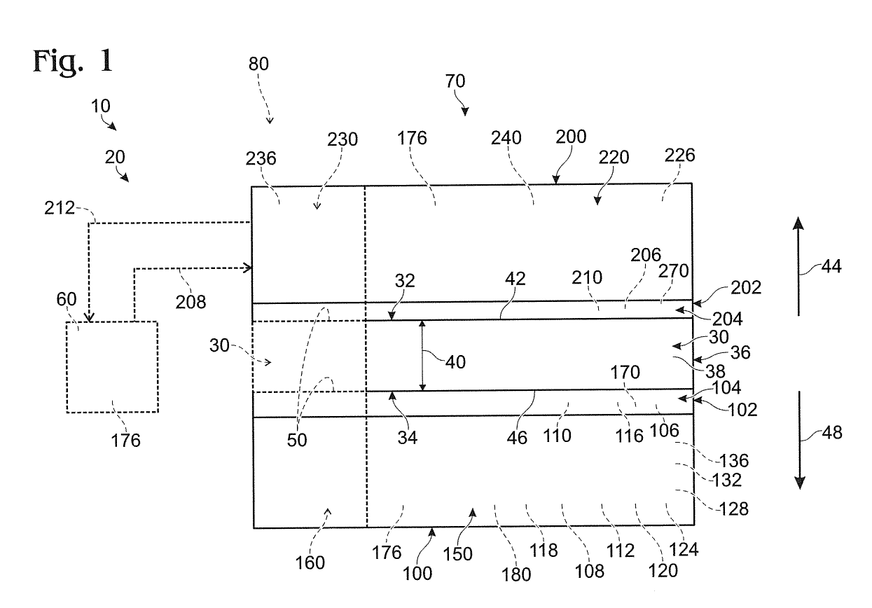

FIG. 1 provides a schematic representation of illustrative, non-exclusive examples of a test assembly 20 according to the present disclosure that is configured to electrically contact a device under test (DUT) 30, such as in connection with probing and/or testing of the DUT. Accordingly, test assembly 20 may form a portion of a test system 10 that includes test assembly 20, as well as a test signal generation and analysis system 60. Test assembly 20 includes test fixture 100 and probe head 200. Test fixture 100 and probe head 200, respectively, each include a contacting structure 104, 204 that is configured to electrically contact at least a portion of DUT 30. Additionally or alternatively, test fixture 100 and/or probe head 200 also may include any other suitable communication linkage 102, 202 that is configured to provide for the transfer of any suitable signal to and/or from DUT 30 through the use of any suitable structure.

Test assembly 20 may include a DUT contacting region 70, in which both the probe head and the test fixture electrically contact the DUT. As illustrated in dashed lines in FIG. 1, test assembly 20 optionally also may (and thus is not required to) include a test fixture-probe head contacting region 80, in which a portion of probe head 200 electrically contacts a portion of test fixture 100.

DUT 30 may be or include any suitable electronic device 38 that may be electrically contacted by test assembly 20 and/or electrically tested by test system 10. Illustrative, non-exclusive examples of DUT 30 and/or electronic device 38 according to the present disclosure include any suitable semiconductor device, transistor, resistor, capacitor, inductor, electrical conductor, contact, via, through silicon via, pad, metal line, interposer, processor circuit, memory circuit, integrated circuit, application specific integrated circuit, logic circuit, sensor circuit, system on a chip, power supply circuit, space transformer, microelectronic device, microprocessor, solar cell, and/or power control circuit.

DUT 30 and/or electronic device 38 may be manufactured, created, and/or fabricated in any suitable manner. As an illustrative, non-exclusive example, DUT 30 may be fabricated on and/or from a portion of a semiconductor device, a semiconductor wafer, a silicon wafer, a gallium arsenide wafer, and/or any suitable substrate, or substrate material. When DUT 30 forms (and/or was formed as) a portion of a semiconductor wafer, DUT 30 may include an entire semiconductor wafer, a portion of the semiconductor wafer, a plurality of singulated die from a semiconductor wafer, one or more singulated die that are mounted on adhesive tape, a plurality of non-singulated die from a semiconductor wafer, and/or an individual die from a semiconductor wafer. Although not required to all embodiments, DUT 30 may form a portion of, a layer of, and/or a precursor to a stacked semiconductor device, a composite semiconductor device, a 2.5-dimensional integrated circuit, and/or a 3-dimensional integrated circuit.

DUT 30 may include any suitable form, form factor, shape, and/or configuration. As an illustrative, non-exclusive example, DUT 30 may be a planar, or at least substantially planar, DUT that includes a front side 32 and a back side 34, with the front side being at least substantially opposed to the back side. As used herein, “at least substantially” is intended to include a range of values from “substantially” to “completely.” Thus, and as an illustrative, non-exclusive example, an at least substantially planar DUT may be described as being substantially planar, essentially planar, or planar. As used herein, front side 32 and back side 34 may, additionally or alternatively, be referred to as a top side 32 and a bottom side 34 and/or as a first side 32 and a second side 34 that is opposed, or at least substantially opposed, to first side 32.

When DUT 30 is an at least substantially planar DUT, front side 32 may form a first major surface of the DUT, back side 34 may form a second major surface of the DUT, and the DUT also may include one or more edge, or minor, surfaces 36. A surface area of the first major surface and the second major surface may form a substantial portion of a surface area of DUT 30. As an illustrative, non-exclusive example, the surface area of the first major surface and the second major surface may form a majority of the surface area of DUT 30, and/or may form at least 50%, at least 60%, at least 70%, at least 80%, at least 90%, at least 95%, at least 97%, at least 98%, at least 99%, at least 99.5%, or at least 99.9% of the surface area of DUT 30.

DUT 30 may have any suitable thickness. As an illustrative, non-exclusive example, when DUT 30 is an at least substantially planar DUT, the thickness of DUT 30 may be less than 1000 micrometers, less than 500 micrometers, less than 250 micrometers, less than 100 micrometers, less than 90 micrometers, less than 80 micrometers, less than 70 micrometers, less than 60 micrometers, less than 50 micrometers, less than 40 micrometers, less than 30 micrometers, less than 20 micrometers, or less than 10 micrometers. Thicknesses that are larger than or within these illustrative, non-exclusive examples are also within the scope of the present disclosure and also may apply to a DUT 30 that is not an at least substantially planar DUT. As used herein, the thickness of DUT 30 refers to an overall thickness 40 of DUT 30.

Front side 32 of DUT 30 includes at least one front side electrical pad 42, while back side 34 of DUT 30 includes at least one back side electrical pad 46. As schematically illustrated in FIG. 1, front side electrical pad 42 may be described as facing and/or being accessible from a front side direction 44, and back side electrical pad 46 may be described as facing and/or being accessible from a back side direction 48. The front and back side directions 44 and 48 additionally or alternatively may be referred to herein as front side and back side surface normal directions 44 and 48, respectively. Although only a single front side electrical pad and a single back side electrical pad are depicted in the schematic illustration of FIG. 1, it is within the scope of the present disclosure that DUT 30 may (and often will) include a plurality of front side electrical pads 42 and/or a plurality of back side electrical pads 46. It is further within the scope of the present disclosure that at least a portion of the front side electrical pad(s) 42 and/or at least a portion of the back side electrical pad(s) 46 may include an at least substantially flat, or planar, contacting surface.

Electrical pads 42, 46 may include any suitable construction that is configured to provide a structure, location, contacting surface, and/or conductive surface that may form a portion of an electrical interface between DUT 30 and test fixture 100, probe head 200, and/or other testing equipment of a test assembly 20 and/or test system 10. As illustrative, non-exclusive examples, electrical pads 42, 46 may include, be, and/or be referred to herein as bond pads, contact pads, landing pads, metallic pads, metallic contacts, contacts, contact points, electrical contact points, solder balls, solder bumps, pillars, and/or wire bond pads.

It is within the scope of the present disclosure that electrical pads 42, 46 may refer to any suitable electrically conductive surface that is designed, configured, constructed, and/or adapted to provide an electrical interface, or connection, between electronic devices 38 of DUT 30 and one or more electronic components, devices, and/or systems that are external to DUT 30. Additionally or alternatively, it is also within the scope of the present disclosure that electrical pads 42, 46 also may refer to an electrically conductive surface that, while not specifically designed, configured, constructed, and/or adapted to provide the electrical interface, may function as the electrical interface. As an illustrative, non-exclusive example, when test assembly 20 and/or test system 10 is utilized to perform standardized and/or automated electrical tests, such as those that may be utilized in a high volume manufacturing environment, electrical pads 42, 46 may refer to bond, landing, and/or contact pads. As another illustrative, non-exclusive example, when test assembly 20 is utilized to perform failure analysis, troubleshooting, and/or manually controlled electrical tests, electrical pads 42, 46 may refer to any suitable electrically conductive surface on or within DUT 30 that may provide the electrical interface.

Electrical pads 42, 46 may be configured to conduct an electric current into and/or out of DUT 30, such as to receive an input signal into the DUT and/or to output a resultant signal from the DUT. The input and output signals each may include an electrical signal. As discussed in more detail herein, it is within the scope of the present disclosure that DUT 30 may include any suitable number and/or configuration of electronic devices 38. It is also within the scope of the present disclosure that at least a portion of electronic devices 38 may electrically interconnect and/or form an electrical conduit for a flow of electric current between at least a portion of front side electrical pads 42 and at least a portion of back side electrical pads 46, between a first portion of front side electrical pads 42 and a second portion of front side electrical pads 42, and/or between a first portion of back side electrical pads 46 and a second portion of back side electrical pads 46.

Test fixture 100 may include any suitable structure that is configured to electrically contact and/or form an electrical connection with at least a portion of DUT 30, such as one or more back side electrical pads 46 thereof. It is within the scope of the present disclosure that test fixture 100 also may route, relocate, or otherwise establish a pathway for electrical communication between at least a portion of back side electrical pads 46 and one or more auxiliary pads 50. As discussed in more detail herein, auxiliary pads 50 may be positioned or configured to be accessed from proximate and/or from a different direction than back side electrical pads 46 and/or from proximate and/or from the same general direction as front side electrical pad(s) 42 of the DUT and, as indicated in dashed lines in FIG. 1 and also discussed in more detail herein, may be present at any suitable relative height with respect to front side 32 of DUT 30 and/or may form a portion of front side 32. Illustrative, non-exclusive examples of test fixtures 100 according to the present disclosure include any suitable interposer, receptacle, socket, wafer, semiconductor wafer, silicon wafer, carrier wafer, smart wafer, translator wafer, handling wafer, wafer chuck, die seat, tray, and/or die tray.

As an illustrative, non-exclusive example, test fixture 100 may include one or more electrical conduits, or interposers, 108 that are configured to provide an electrical connection between one or more back side electrical pads 46 and one or more auxiliary pads 50. As another illustrative, non-exclusive example, test fixture 100 additionally or alternatively may include any suitable receptacle 118 that is configured to receive, or accept, at least a portion of DUT 30. As yet another illustrative, non-exclusive example, test fixture 100 further additionally or alternatively may include a carrier wafer, or smart wafer, 124 that, in addition to forming one or more electrical connections with DUT 30, provides for the routing of electrical signals to DUT 30, provides for the routing of electrical signals from DUT 30, generates at least a portion of the electrical signals that may be supplied to DUT 30, and/or receives, filters, processes, and/or analyzes at least a portion of the electrical signals that may be received from DUT 30.

It is within the scope of the present disclosure that test fixture 100, including any of the illustrative, non-exclusive examples of test fixture 100 that are disclosed herein, may include, contain, and/or be in electrical communication with any suitable electrical structure 180. Illustrative, non-exclusive examples of electrical structures according to the present disclosure include any suitable semiconductor device, passive electronic component, resistor, capacitor, inductor, electrical conductor, via, through silicon via, pad, metal line, interposer, space transformer, active electronic component, transistor, processor circuit, memory circuit, integrated circuit, application specific integrated circuit, logic circuit, sensor circuit, system on a chip, power supply circuit, microelectronic device, microprocessor, and/or power control circuit.

As yet another illustrative, non-exclusive example, when DUT 30 includes and/or forms a portion of a semiconductor wafer, test fixture 100 optionally may include a wafer chuck 128 that is configured to hold, retain, and/or locate the DUT. As yet another illustrative, non-exclusive example, when DUT 30 includes one or more individual die, test fixture 100 optionally may include a die seat 132 that is configured to hold, retain, and/or make electrical contact with the DUT.

Die seat 132 may be contained within, operatively attached to, and/or form a portion of a die tray 136 that is configured to hold, or contain, one or more die seats 132, together with their associated DUTs 30. When test fixture 100 includes die tray 136, die tray 136 may include any suitable number of (i.e., one, two, more than two, etc.) die seats 132. Die seats 132 may be integrated into, formed with, form a portion of, and/or permanently attached to die tray 136, and/or at least a portion of die seats 132 may be configured to be separated and/or removed from die tray 136 (and optionally returned thereto and/or reused therein). As an illustrative, non-exclusive example, at least a portion of die seats 132 may be configured to be removed from die tray 136 for repair and/or replacement. As another illustrative, non-exclusive example, at least a portion of die seats 132 may be DUT-specific die seats that are configured for form an electrical connection with a specific DUT, such as which includes a specific back side electrical pad layout. Moreover, different DUT-specific die seats may be utilized in die tray 136, such as depending upon a particular back side electrical pad layout of a particular DUT being tested.

Test fixture 100 also may include one or more alignment structures 112 that are configured to align DUT 30 within the test fixture. Alignment structures 112 according to the present disclosure may include any suitable structure that may align, or otherwise position, DUT 30 to within a threshold position and/or a threshold tolerance of a desired location within test fixture 100. When test fixture 100 includes alignment structures 112, alignment structures 112 may be configured to align DUT 30 relative to any suitable reference point, or reference structure, on DUT 30 and/or test fixture 100.

Illustrative, non-exclusive examples of suitable reference structures on DUT 30 according to the present disclosure include an edge of DUT 30, a corner of DUT 30, an electrical structure on DUT 30, an electrical pad on DUT 30, a through silicon via (TSV) on DUT 30, an optical structure on DUT 30, and/or a lithographically defined feature on DUT 30. Illustrative, non-exclusive examples of suitable alignment structures 112 of test fixture 100 include any suitable passive alignment structure, sloped surface, tapered sidewall, active alignment structure, stepper motor, and/or piezoelectric positioner.

The threshold tolerance may be any suitable threshold tolerance. As an illustrative, non-exclusive example, contacting structure 104 may include one or more electrical contacts 110 that are configured to form an electrical connection between one or more back side electrical pads 46 of DUT 30 and test fixture 100. Furthermore, back side electrical pads 46 may include a characteristic dimension, characteristic extent, and/or characteristic pitch, and the threshold tolerance may be a threshold amount of the characteristic dimension, such as to provide for electrical contact between back side electrical pads 46 and electrical contacts 110.

Illustrative, non-exclusive examples of threshold amounts of the characteristic dimension include threshold amounts of less than 50%, less than 40%, less than 30%, less than 25%, less than 20%, less than 15%, less than 10%, less than 5%, less than 4%, less than 3%, less than 2%, or less than 1% of the characteristic dimension. Illustrative, non-exclusive examples of characteristic dimensions according to the present disclosure include characteristic dimensions of less than 250 micrometers, less than 200 micrometers, less than 150 micrometers, less than 125 micrometers, less than 100 micrometers, less than 90 micrometers, less than 80 micrometers, less than 70 micrometers, less than 60 micrometers, less than 50 micrometers, less than 40 micrometers, less than 30 micrometers, less than 20 micrometers, less than 15 micrometers, less than 10 micrometers, less than 5 micrometers, less than 4 micrometers, less than 3 micrometers, less than 2 micrometers, less than 1 micrometer, less than 0.75 micrometers, less than 0.5 micrometers, less than 0.25 micrometers, or less than 0.1 micrometer.

Test fixture 100 includes at least one test fixture region 150, which also may be referred to herein as a portion, zone, and/or section of the test fixture, that is configured to form an electrical connection between the test fixture and DUT 30. Thus, while test fixture 100 may include a single test fixture region 150, it is within the scope of the present disclosure that test fixture region 150 may be a first test fixture region 150, and that text fixture 100 optionally also may include a second test fixture region 160 that is configured to form an electrical connection between the test fixture and probe head 200. When test fixture 100 includes second test fixture region 160, second test fixture region 160 may include and/or contain auxiliary pads 50. FIG. 1 illustrates first test fixture region 150 and optional second test fixture region 160, but it is within the scope of the present disclosure that test fixtures 100 further optionally may include a plurality of test fixture regions, including three, four, five, ten, or more than ten test fixture regions.

Probe head 200 may include any suitable structure that is configured to electrically contact, or form an electrical connection with, at least a portion of DUT 30 and/or auxiliary pads 50 of test fixture 100 through the use of contact structure 204. Illustrative, non-exclusive examples of probe heads and/or features that may be utilized with probe heads 200, test assemblies 20, and/or test systems 10 according to the present disclosure are disclosed in U.S. Provisional Patent Application Ser. No. 61/446,379, in U.S. Patent Application Publication No. US-2012-0112779-A1 in U.S. patent application Ser. No. 13/463,712, and in U.S. Pat. Nos. 5,914,613, 6,256,882, and 7,862,391, the complete disclosures of which are hereby incorporated by reference.

Probe head 200 is configured to receive a test signal 208 from test signal generation and analysis system 60 and to provide the test signal to DUT 30. Probe head 200 additionally or alternatively may be configured to receive a resultant signal 212 from DUT 30 and to provide the resultant signal to test signal generation and analysis system 60. Probe head 200 includes at least one probe head region 220 that is configured to provide an electrical connection between probe head 200 and DUT 30. Similar to the preceding discussion of test fixture 100, it is within the scope of the present disclosure that probe head region 220 may be a first probe head region 220 and that probe head 200 optionally also may include at least a second probe head region 230 that is configured to provide an electrical connection between probe head 200 and test fixture 100.

Probe head 200 is configured to be moved into and/or out of contact with DUT 30 and/or test fixture 100, such as by being moved into and/or out of electrical and/or physical contact with the DUT and/or the test fixture. Thus, during a testing operation, DUT 30 may be placed (or already be) in electrical communication with test fixture 100 and placed (or already be) beneath probe head 200. Probe head 200 may then be moved into electrical communication with DUT 30 and/or test fixture 100, such as by moving one or more contacting structures 204 of probe head 200 toward one or more front side electrical pads 42 of DUT 30 and/or one or more auxiliary pads 50 of test fixture 100 and/or DUT 30. This moving may include moving probe head 200 in a direction that is at least substantially similar to back side direction 48 and/or in a direction that is at least substantially opposed to front side direction 44. Additionally or alternatively, this moving may include moving DUT 30 in a direction that is at least substantially similar to front side direction 44 and/or moving DUT 30 in a direction that is at least substantially opposed to back side direction 48. In other words, one or more of the probe head and the DUT may be described as being moved to establish contact between the probe head and at least the front side pad(s) of the DUT, and more commonly, the front side electrical pads and the auxiliary pads. Additionally or alternatively, the probe head may be described as being moved toward the front side of the DUT from a position in which the probe head generally faces the front side of the DUT, and optionally, the auxiliary pads.

Moving probe head 200 into and/or out of contact with DUT 30 and/or test fixture 100 may include aligning probe head 200 with DUT 30 and/or test fixture 100 and/or adjusting a planarity of probe head 200 with respect to DUT 30 and/or test fixture 100. This aligning may include the use of one or more alignment structures 240 that are configured to provide a reference point for and/or structurally locate and/or align probe head 200 with test fixture 100 and/or DUT 30, including the illustrative, non-exclusive examples of alignment structures 112 discussed in more detail herein. Additionally or alternatively, this aligning may include aligning and/or adjusting an orientation of a plane defined by probe head 200 to be at least substantially parallel to a plane defined by DUT 30 and/or test fixture 100.

Moving probe head 200 into and/or out of contact with DUT 30 and/or test fixture 100 also may include adjusting a compliance of the probe head. Adjusting the compliance of the probe head may include adjusting a force that is applied to the front side electrical pads and/or the auxiliary pads by contacting structure 204.

When probe head 200 includes first probe head region 220 and second probe head region 230, it is within the scope of the present disclosure that first probe head region 220 and second probe head region 230 may form respective portions of single, integrated probe head 200. This single, integrated probe head may include a first contact engine 226 that is associated with first probe head region 220 and a second contact engine 236 that is associated with second probe head region 230. The first and second probe head regions may be configured to adjust the planarity and/or the compliance of the first probe head region and/or the second probe head region with respect to the respective portion(s) of DUT 30 and/or test fixture 100 that they contact. This adjusting may include adjusting the planarity and/or the compliance of the first probe head region separately from, without regard for, and/or independently from the planarity and/or the compliance of the second probe head region.

Adjusting the planarity and/or compliance of the first probe head region and/or the second probe head region may include adjusting the planarity and/or compliance based, at least in part, on a variable associated with the first probe head region and/or the second probe head region. Illustrative, non-exclusive examples according to the present disclosure of variables associated with the first probe head region and/or variables associated with the second probe head region include an orientation of the first probe head region and/or the second probe head region with respect to the front side electrical pad and/or the auxiliary pad, respectively, a force applied to the front side electrical pad and/or the auxiliary pad by the first probe head region and/or the second probe head region, respectively, and/or a force gradient across a surface of the first probe head region and/or the second probe head region due to and/or resulting from contact with the front side electrical pad and/or the auxiliary pad, respectively.

Contacting structures 104, 204 may include any suitable structure that is configured to provide an electrical connection between test fixture 100 and DUT 30, between DUT 30 and probe head 200, and/or between text fixture 100 and probe head 200. Illustrative, non-exclusive examples of contacting structures 104, 204 that may be utilized with the systems, devices, and/or methods according to the present disclosure include any suitable electrical contact 110, 210, such as any suitable contacting tip 116, 216, which also may be referred to as a probe tip and/or probe contact.

Contacting structures 104 that are associated with first test fixture region 150 and/or second test fixture region 160 optionally may include and/or be a plurality of electrical contacts 110, such as contacting tips 116. Moreover, it is within the scope of the present disclosure that at least a portion of a plurality of contacting tips associated with first test fixture region 150 may be at least substantially similar to (and/or the same as) a portion of the plurality of contacting tips associated with second test fixture region 160, and/or that at least a portion of the plurality of contacting tips associated with first test fixture region 150 may be different from a portion of the plurality of contacting tips associated with second test fixture region 160. Similarly, it is also within the scope of the present disclosure that contacting structures 204 associated with first probe head region 220 and/or second probe head region 230 may include a plurality of electrical contacts 210, such as contacting tips 216, that at least a portion of the plurality of contacting tips associated with first probe head region 220 may be at least substantially similar to a portion of the plurality of contacting tips associated with second probe head region 230, and/or that at least a portion of the plurality of contacting tips associated with first probe head region 220 may be at least substantially different from a portion of the plurality of contacting tips associated with second probe head region 230.

It is also within the scope of the present disclosure that contacting structures 104, 204 may be in electrical communication with one or more interface regions 170, 270 that are configured to provide, complete, and/or facilitate the electrical connection between test fixture 100 and DUT 30, between probe head 200 and DUT 30, and/or between test fixture 100 and probe head 200. Interface regions 170, 270 may include any suitable structure that is configured to provide the electrical connection. As an illustrative, non-exclusive example, interface regions 170, 270 may be and/or include a compliant structure, a conductive material, a polymer, a conductive polymer, an anisotropically conductive polymer, a metal, a conductive grid, a conductive sheet, and/or a patterned conductive surface.

When interface regions 170, 270 include an anisotropically conductive polymer, the anisotropically conductive polymer may be configured to conduct electrical current in a direction that is at least substantially parallel to the front side direction and/or the back side direction but not in a direction that is at least substantially perpendicular to the front side direction and/or the back side direction. When interface regions 170, 270 include a compliant structure, the compliant structure associated with interface region 170 may include a first compliance that is at least substantially similar to, or even the same as, a second compliance of the compliant structure associated with interface region 270.

However, it is within the scope of the present disclosure that the first compliance may be different from the second compliance. As an illustrative, non-exclusive example, the first compliance may be greater than the second compliance. Under these conditions, a deformation associated with interface region 170 may be greater than a deformation associated with interface region 270 when probe head 200 is in electrical communication with DUT 30 and/or test fixture 100. Alternatively, the first compliance may be less than the second compliance. Under these conditions, the deformation associated with interface region 170 may be less than the deformation associated with interface region 270. When the first compliance is different from the second compliance, a deformation of the DUT (when the DUT is present within the test assembly and in electrical contact with both test fixture 100 and probe head 200) may be governed, directed, or otherwise controlled by a deformation and/or flatness of the lower compliance surface, which may provide for decreasing the deformation of the DUT through control of the flatness of the lower compliance surface.

As discussed in more detail herein, auxiliary pads 50 may be configured to be in electrical communication with back side electrical pads 46 and may be configured to form an electrical connection with probe head 200, such as with contact structure 204 of probe head 200. Auxiliary pad 50 may include any suitable construction, including the illustrative, non-exclusive examples of pad construction that are discussed in more detail herein with reference to front side electrical pad 42 and/or back side electrical pad 46, and auxiliary pads 50 also may be referred to herein as supplemental pads, accessory pads, mapped pads, relocated pads, and/or rerouted pads.

Auxiliary pads 50 may form a portion of any suitable component(s) of test assembly 20. As an illustrative, non-exclusive example, at least a portion of auxiliary pads 50 may form a portion of, be operatively attached to, and/or be fabricated with test fixture 100. When auxiliary pads 50 form a portion of test fixture 100, probe head 200 may be configured to form an electrical connection both with DUT 30 and with test fixture 100.

As another illustrative, non-exclusive example, at least a portion of auxiliary pads 50 may include one or more front side electrical pads 42 of DUT 30. When auxiliary pads 50 include one or more front side electrical pads 42 of DUT 30, probe head 200 may be configured to form an electrical connection with at least a first front side electrical pad 57 of DUT 30 that is not functioning as an auxiliary pad and also with at least a second front side electrical pad 59 of DUT 30 that functions as an auxiliary pad. When DUT 30 includes an individual die, both the front side electrical pad and the auxiliary pad may be part of the individual die. However, it is also within the scope of the present disclosure that, when DUT 30 includes a plurality of die, the front side electrical pad and the auxiliary pad may be part of the same and/or different die.

Auxiliary pads 50 may face in a direction, and/or define an auxiliary pad surface normal direction, that is different from a direction of back side electrical pads 46 and/or back side surface normal direction 48. As an illustrative, non-exclusive example, the auxiliary pad surface normal direction may be generally opposed to the back side surface normal direction and/or at least substantially similar to and/or in the same direction as front side surface normal direction 44.

Additionally or alternatively, the auxiliary pad surface normal direction may be within a threshold angle of the front side surface normal direction. Illustrative, non-exclusive examples of threshold angles according to the present disclosure include threshold angles of less than 90 degrees, less than 80 degrees, less than 70 degrees, less than 60 degrees, less than 50 degrees, less than 40 degrees, less than 30 degrees, less than 20 degrees, less than 15 degrees, less than 10 degrees, less than 5 degrees, less than 4 degrees, less than 3 degrees, less than 2 degrees, or less than 1 degree.

As discussed in more detail herein, test assembly 20 may form a portion of test system 10, which also may include one or more test signal generation and analysis systems 60. Test signal generation and analysis system 60 may be configured to provide test signal 208 to and/or receive resultant signal 212 from test assembly 20, DUT 30, front side electrical pad 42, back side electrical pad 46, and/or auxiliary pad 50. Illustrative, non-exclusive examples of test signal generation and analysis systems 60 include any suitable probe system, function generator, signal generator, spectrum analyzer, and/or impedance spectrometer.

Test signal generation and analysis system 60 may be configured to generate or otherwise supply or provide any suitable test signal 208, illustrative, non-exclusive examples of which include any suitable DC test signal, AC test signal, radio frequency (RF) test signal, and/or microwave frequency (MF) test signal. Similarly, test signal generation and analysis system 60 also may be configured to receive any suitable resultant signal 212, illustrative, non-exclusive examples of which include any suitable DC resultant signal, AC resultant signal, RF resultant signal, and/or MF resultant signal.

Additionally and/or alternatively, test signal generation and analysis system 60 also may be configured to receive a null resultant signal. By null resultant signal, it is meant that the resultant signal may not be present, may not be present when it was expected to be present, may not be present when it was not expected to be present, may include a zero voltage resultant signal, and/or may include a zero current resultant signal. As an illustrative, non-exclusive example, when there is an unexpected electrical open between a front side electrical pad and an auxiliary pad, between two front side electrical pads, and/or between two back side electrical pads, a test signal that is supplied to one of the electrical pads may not produce a resultant signal to be returned to the test signal generation and analysis system from the other of the electrical pads. As another illustrative, non-exclusive example, when there is an unexpected electrical short between two electrical pads, a test signal that is supplied to one of the electrical pads may produce an unexpected resultant signal that may be returned to the test signal generation and analysis system.

Test signal generation and analysis system 60 may be configured to analyze the resultant signal that is produced by test assembly 20 and/or DUT 30. Test assembly 20 and/or test signal generation and analysis system 60 optionally may include and/or be in electrical communication with electrical compensation hardware and/or software configured to compensate for non-idealities in the test signal, the resultant signal, the DUT, the test fixture, the probe head, and/or the test assembly and to improve the quality of the analysis results that may be produced by test signal generation and analysis system 60.

Test signal generation and analysis system 60 may be configured to perform any suitable electrical test on DUT 30. As an illustrative, non-exclusive example, test signal generation and analysis system 60 may be configured to test for continuity, open circuits, and/or short circuits between and/or among any suitable number of front side electrical pads and/or back side electrical pads of DUT 30. As another illustrative, non-exclusive example, this testing may include electrically connecting at least a first through silicon via (TSV) of DUT 30 to at least a second TSV of DUT 30 using test fixture 100. Additionally and/or alternatively, the at least a first TSV and/or the at least a second TSV also may include a plurality of TSVs.

As yet another illustrative, non-exclusive example, this testing may include testing the functionality of one or more electronic devices 38 associated with DUT 30. It is within the scope of the present disclosure that testing the functionality of electronic devices 38 may include comparing the resultant signal to an expected resultant signal and/or determining if the resultant signal is between a first predetermined threshold value and a second predetermined threshold value. Additionally and/or alternatively, this testing also may include categorizing the performance of DUT 30 and/or electronic device 38 based at least in part on the value of the resultant signal.

The testing additionally or alternatively may include testing a plurality of front side electrical pads 42 and/or a plurality of back side electrical pads 46 that may be in electrical communication with a plurality of electronic devices 38. This testing may include sequentially testing at least a portion of the plurality of front side electrical pads, back side electrical pads, and/or electronic devices. Additionally or alternatively, this testing also may include simultaneously testing at least a portion of the plurality of front side electrical pads, back side electrical pads, and/or electronic devices.

As shown in FIG. 1, contacting structure 104 associated with test fixture 100 and/or contacting structure 204 associated with probe head 200 also may include one or more force balance tips 106, 206, respectively, that are configured to apply a force to DUT 30. The force balance tips 106, 206 may be present in any suitable location on test fixture 100 and/or probe head 200 and may be utilized to balance, equalize, and/or distribute a force that is applied to DUT 30 by contact with test fixture 100 and/or probe head 200.

As an illustrative, non-exclusive example, DUT 30 may be deformed by a contact force that is applied to DUT 30 by contacting structures 104, 204, such as by electrical contacts 110, 210, contacting tips 116, 216 and/or interface regions 170, 270 thereof. When DUT 30 is deformed by the contact force, one or more force balance tips 106, 206 may be utilized to distribute the contact forces that are applied to DUT 30 across a surface of DUT 30, to equalize the contact forces that are applied to the front side of DUT 30 with those that are applied to the back side of DUT 30, and/or to provide an opposing force that is at least substantially equal and opposite to a force that is applied to DUT 30 by contacting structures 104, 204, such as by electrical contacts 110, 210 and/or contacting tips 116, 216.

As shown in dashed lines in FIG. 1, a portion of test system 10, such as test assembly 20, test signal generation and analysis system 60, test fixture 100, and/or probe head 200 thereof optionally may include and/or be in thermal communication with a thermal management system 176 that is configured to supply thermal energy to and/or remove thermal energy from the portion of test system 10. As an illustrative, non-exclusive example, the supply of test signal 208 to, and/or the production of resultant signal 212 by, DUT 30 may include and/or result in the production of heat within test system 10, and thermal management system 176 may be configured to remove the heat produced within test system 10. As another illustrative, non-exclusive example, the generation of heat within test system 10 may produce a thermal gradient across a portion of test assembly 20, and thermal management system 176 may be configured to decrease a magnitude of the thermal gradient.

As yet another illustrative, non-exclusive example, thermal management system 176 may be configured to maintain a temperature of the portion of test system 10 at, at approximately, near, and/or within a determined range of a threshold temperature. As yet another illustrative, non-exclusive example, thermal management system 176 may be configured to maintain the temperature of the portion of test system 10 above a lower threshold temperature and/or below an upper threshold temperature (i.e., within determined upper and lower threshold temperatures). Illustrative, non-exclusive examples of thermal management systems 176 according to the present disclosure may include any suitable thermal management fluid, heat exchanger, closed loop heat exchange system, throttle valve, evaporator, condenser, air conditioner, fan, blower, compressor, air management system, Peltier device, temperature detector, and/or temperature controller.

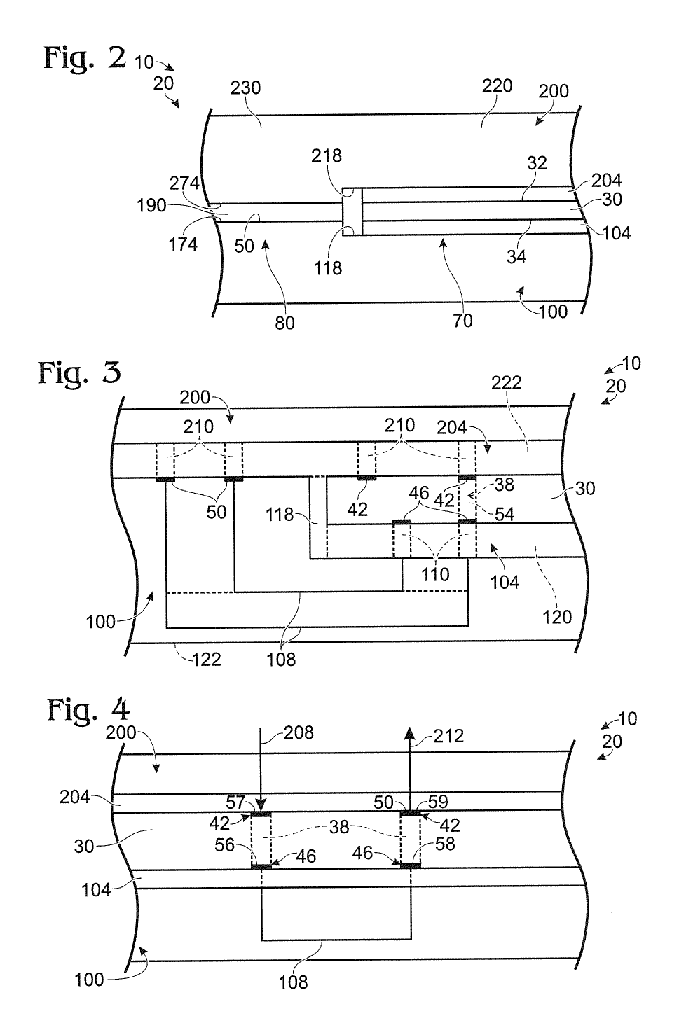

FIG. 2 provides a less schematic but still illustrative, non-exclusive example of a test assembly 20 according to the present disclosure. The test assembly of FIG. 2 is at least substantially similar to that of FIG. 1 and similar elements will not be (re)discussed in detail herein. In FIG. 2, test fixture 100 includes a receptacle 118 that is configured to receive DUT 30, and probe head 200 also includes a receptacle 218 that is configured to receive DUT 30. Receptacles 118, 218 may have any suitable form and/or structure, and may be or include at least one recess, socket, or other structure that is configured to receive at least a portion of DUT 30.

The illustrative, non-exclusive example of test assembly 20 that is shown in FIG. 2 also provides a graphical (albeit schematic) example of a test assembly that includes a DUT contacting region 70 that is associated with first probe head region 220, as well as a test fixture-probe head contacting region 80 that is associated with second probe head region 230. In DUT contacting region 70, contacting structures 104, 204 are configured to provide electrical contact between test fixture 100 and probe head 200, respectively, and DUT 30. Similarly, in test fixture-probe head contacting region 80, test fixture-probe head contacting structure 190 is configured to provide an electrical connection between test fixture 100 and probe head 200. It is within the scope of the present disclosure that test fixture-probe head contacting structure 190 may be at least substantially similar, or identical, to the contacting structures 104, 204 that are discussed in more detail herein and may electrically contact auxiliary pads 50 of test fixture 100.

Receptacles 118, 218 may include any suitable structure based on any suitable criteria, such as associated with the DUT to be received, the probing and/or testing to be performed, any interposers to be used, etc. As an illustrative, non-exclusive example, a size of receptacles 118, 218 may be determined based at least in part upon a size of DUT 30. As another illustrative, non-exclusive example, a size of receptacles 118, 218 may be selected based upon a predetermined, or desired, relative orientation of DUT 30 with respect to test fixture 100 and/or probe head 200. As a further illustrative, non-exclusive example, receptacle 118 may be sized such that front side 32 of DUT 30 is at least substantially coplanar with a top surface 174 of test fixture 100, which may provide for the use of a test fixture-probe head contacting structure 190 that is at least substantially coplanar with contacting structure 204. When the front side of DUT 30 is at least substantially coplanar with the top surface of test fixture 100, it is within the scope of the present disclosure that probe head 200 may not include receptacle 218.

As another illustrative, non-exclusive example, receptacle 218 may be sized such that back side 34 of DUT 30 is at least substantially coplanar with bottom surface 274 of probe head 200, which may provide for the use of a test fixture-probe head contacting structure 190 that is at least substantially coplanar with contacting structure 104. When the back side of DUT 30 is at least substantially coplanar with the bottom surface of probe head 200, it is within the scope of the present disclosure that test fixture 100 may not include receptacle 118.

As yet another illustrative, non-exclusive example, and as shown in FIG. 2, the front and/or back surfaces of DUT 30 optionally may not be coplanar with the top and/or bottom surfaces of the test fixture and/or the probe head, respectively. Under these conditions, test assembly 20 may include both receptacle 118 and receptacle 218.

FIG. 3 provides another less schematic but still illustrative, non-exclusive example of a test assembly 20 according to the present disclosure. In FIG. 3, test fixture 100 includes a contacting structure 104 that may include a plurality of electrical contacts 110 and/or compliant structure 120 that are configured to provide an electrical connection between test fixture 100 and back side electrical pads 46 of DUT 30. In addition, test fixture 100 also includes a plurality of electrical conduits 108 that are configured to provide an electrical connection between the plurality of electrical contacts 110 and a plurality of auxiliary pads 50. DUT 30 is contained within receptacle, or recess, 118 such that the plurality of auxiliary pads 50 are at least substantially, approximately, or nearly coplanar with a plurality of front side electrical pads 42 of the DUT and/or such that the plurality of front side electrical pads 42 and the auxiliary pads 50 are positioned at least substantially the same distance away from a plane defined by the back side of the device under test. Additionally or alternatively, and as discussed in more detail herein, it is also within the scope of the present disclosure that the plurality of auxiliary pads 50 may not be coplanar with the plurality of front side electrical pads 42 and/or that the plurality of front side electrical pads 42 and the auxiliary pads 50 may be positioned at different distances away from a plane defined by the back side of the device under test.

Probe head 200 includes contacting structure 204, which may include electrical contacts, or contacting tips 216, and/or compliant structure 222 that are configured to provide an electrical connection between the probe head and the plurality of auxiliary pads 50, as well as to provide an electrical connection between the probe head and the plurality of front side electrical pads 42. While not required in all embodiments, the at least substantially coplanar geometry of front side electrical pads 42 with respect to auxiliary pads 50 may facilitate, ease, or otherwise simplify forming an electrical connection between electrical pads 42, auxiliary pads 50, and probe head 200, such as by providing for the use of a single probe head to contact both front side electrical pads 42 and auxiliary pads 50, simplifying the process of contacting probe head 200 with front side electrical pads 42 and auxiliary pads 50, and/or simplifying the structure of probe head 200 that may be needed to accurately, reliably, and/or reproducibly contact front side electrical pads 42 and auxiliary pads 50.

As discussed in more detail herein, electrical conduits 108 may be configured to form an electrical connection between and/or among back side electrical pads 46 and auxiliary pads 50. This electrical connection may include any suitable electrically conductive relationship between the back side electrical pads and the auxiliary pads. As an illustrative, non-exclusive example, electrical conduits 108 may form a discrete electrical connection between a selected one of the back side electrical pads of DUT 30 and a selected one of the auxiliary pads. As another illustrative, non-exclusive example, electrical conduits 108 may form an electrical connection between a plurality of back side electrical pads 46 and a selected one of the auxiliary pads. As yet another illustrative, non-exclusive example, electrical conduits 108 may form an electrical connection between a selected one of the back side electrical pads and a plurality of auxiliary pads 50. As yet another illustrative, non-exclusive example, electrical conduits 108 may electrically connect, or short, selected ones, a portion, a majority, and/or all of the plurality of back side electrical pads 46 together such that they are in electrical communication with one another. As another illustrative, non-exclusive example, when DUT 30 includes a plurality of die, it is within the scope of the present disclosure that electrical conduits 108 may electrically connect selected ones of the plurality of back side electrical pads of a first die together with selected ones of the plurality of back side electrical pads of a second die.

As yet another illustrative, non-exclusive example, test fixture 100 may include and/or be in electrical communication with one or more switching structures 122 that are configured to selectively provide and/or remove an electrically conductive pathway between and/or among two or more of the plurality of electrical conduits 108. This may include the use of switching structure 122 to selectively change between and/or among two or more of the electrically conductive relationships between back side electrical pads 46 and auxiliary pads 50 that are disclosed herein. This optional use of switching structure 122 may enable two or more tests to be performed on the DUT with test fixture 100 without repositioning the DUT and/or the probe assembly relative to the test fixture and/or each other.

As an illustrative, non-exclusive example, testing of DUT 30 may include performing at least a first electrical test and a second (different) electrical test. The first electrical test may include the use of switching structures 122 to place at least a portion of back side electrical pads 46 of DUT 30 in electrical communication with one another and then test for unexpected open circuits among the portion of the back side electrical pads. Additionally, the second electrical test may include the use of switching structures 122 to connect selected ones of the plurality of back side electrical pads 46 to selected ones of the plurality of auxiliary pads 50 in order to perform additional electrical testing, such as for short circuits, circuit functionality, and/or circuit performance of electronic devices 38 of DUT 30.

Electrical conduit 108 may include any suitable structure that is configured to provide an electrical connection between back side electrical pad 46 and auxiliary pad 50. Illustrative, non-exclusive examples of electrical conduits 108 according to the present disclosure include any suitable electrical conductor, metal line, conductive conduit, interposer, contact, via, TSV, wire, conductive sheet, and/or compliant conductive structure.

Electrical contacts 110, 210 may include any suitable structure that is configured to provide an electrical connection between test fixture 100 and DUT 30, between DUT 30 and probe head 200, and/or between test fixture 100 and probe head 200. Illustrative, nonexclusive examples of electrical contacts 110, 210 that may be utilized with the systems, devices, and/or methods according to the present disclosure are disclosed in U.S. Provisional Patent Application Ser. No. 61/446,379, in U.S. Patent Application Publication No. US-2012-0112779-A1, in U.S. patent application Ser. No. 13/463,712, and in U.S. Pat. Nos. 5,914,613, 6,256,882, and 7,862,391, the complete disclosures of which are hereby incorporated by reference.

As discussed in more detail herein, DUT 30 may include any suitable structure, or electronic device 38, that is configured to conduct electric current between or among a first front side electrical pad and a second front side electrical pad, a first back side electrical pad 56 and a second back side electrical pad 58, and/or a front side electrical pad and a back side electrical pad. As an illustrative, non-exclusive example, DUT 30 may include at least one TSV 54 that is (and in many embodiments will include a plurality of TSVs that are) configured to conduct electric current between a front side electrical pad and a back side electrical pad.

FIG. 4 provides another less schematic but still illustrative, non-exclusive example of a test assembly 20 according to the present disclosure. In FIG. 4, electrical conduit 108 of test fixture 100 is configured to electrically connect a first 56 back side electrical pad 46 of DUT 30 to a second 58 back side electrical pad 46 of DUT 30. Thus, a test signal 208 that is supplied to a first 57 front side electrical pad 42 by probe head 200 may be conducted through an electronic device 38 internal to DUT 30 to first back side electrical pad 56. Electrical conduit 108 may then route, or otherwise direct, the test signal to second back side electrical pad 58, where the test signal may be conducted through another electronic device 38 that is internal to DUT 30 to a second 59 front side electrical pad 42 and produced from the DUT as resultant signal 212.

When test fixture 100 includes electrical conduit 108 that is configured to electrically connect first back side electrical pad 56 with second back side electrical pad 58, second front side electrical pad 59 also may be referred to as an auxiliary pad 50. It is within the scope of the present disclosure that DUT 30 may include a plurality of first front side electrical pads 57, a plurality of second front side electrical pads 59, a plurality of first back side electrical pads 56, and/or a plurality of second back side electrical pads 58. It is also within the scope of the present disclosure that, as discussed in more detail herein, electrical conduit 108 may provide any suitable electrical connection between and/or among the plurality of first back side electrical pads and/or the plurality of second back side electrical pads.

FIG. 5 provides yet another less schematic but still illustrative, non-exclusive example of a test assembly 20 according to the present disclosure. In FIG. 5, test assembly 20 includes a plurality of DUTs 30, including at least first DUT 64 and second DUT 68. In addition, electrical conduits 108 of test fixture 100 are configured to electrically connect first back side electrical pads 56 of first DUT 64 with second back side electrical pads 58 of second DUT 68. Thus, test signal 208 that is supplied to first DUT 64 may be conducted through first DUT 64 to one or more first back side electrical pads 56 and then conducted through electrical conduits 108 of test fixture 100 to second back side electrical pads 58 of second DUT 68 before being produced from second DUT 68 as resultant signal 212.

As shown in dashed lines in FIG. 5, probe head 200 also may be configured to electrically interconnect one or more front side electrical pads 42 of first DUT 64 with one or more front side electrical pads 42 of second DUT 68 using one or more electrical conduits 108. Additionally or alternatively, it is within the scope of the present disclosure that probe head 200 may be configured to electrically interconnect a first front side electrical pad of first DUT 64 with a second front side electrical pad of first DUT 64.

It is within the scope of the present disclosure that first DUT 64 and second DUT 68 may be present within test assembly 20 in any suitable form and/or relative configuration. As an illustrative, non-exclusive example, first DUT 64 and second DUT 68 may form a portion of a silicon wafer that is received within test assembly 20, and scribe line 82 may separate first DUT 64 from second DUT 68. Alternatively, first DUT 64 and second DUT 68 may include separate, discrete, or singulated DUTs that may be separated by a void space 84 and/or by a portion 86 of test fixture 100 and/or die tray 136. FIG. 5 also illustrates that probe head 200 also may include, or be, a test fixture 100 and/or may include a similar construction to that of test fixture 100.

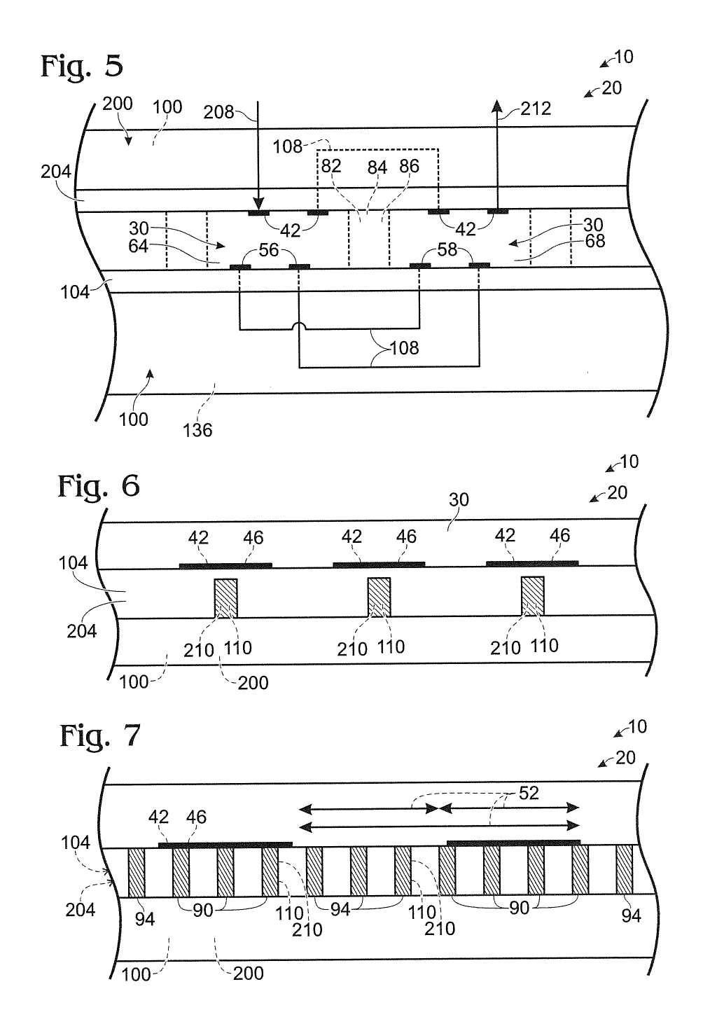

As discussed in more detail herein, contact structures 104, 204 may include any suitable configuration that is configured to provide electrical communication between DUT 30 and test fixture 100 and/or probe head 200. As an illustrative, non-exclusive example, and as shown in FIG. 6, contact structures 104, 204 may include a plurality of electrical contacts 110, 210 that are arranged in complementary locations to a corresponding location of electrical pads 42, 46, respectively. This may include the use of a probe head 200 and/or a test fixture 100 that is specifically designed, configured, or otherwise constructed to provide an electrical connection with a specific DUT 30 that includes specific, or predetermined, locations for electrical pads 42, 46 thereof.

As another illustrative, non-exclusive example, and as shown in FIG. 7, contact structures 104, 204 may include a plurality of electrical contacts 110, 210 that are arranged in a regular, repeating, and/or periodic array and/or in another configuration wherein at least a portion of the contact structures may not be located in complementary locations to the corresponding locations of electrical pads 42, 46, respectively. This may include electrical contacts 110, 210 that are arranged in a periodic array that includes a pitch that is less than a characteristic dimension 52 of electrical pads 42, 46, such as a pitch that is less than 50%, less than 40%, less than 30%, less than 25%, less than 20%, less than 15%, or less than 10% of characteristic dimension 52.

Illustrative, non-exclusive examples of characteristic dimensions 52 according to the present disclosure include any suitable length, pitch, and/or spacing of any suitable structure associated with DUT 30. As an illustrative, non-exclusive example, characteristic dimension 52 may include a size of at least a portion of front side electrical pads 42 and/or at least a portion of back side electrical pads 46. As another illustrative, non-exclusive example, characteristic dimension 52 may include a distance between at least a portion of front side electrical pads 42 and/or at least a portion of back side electrical pads 46. As yet another illustrative, non-exclusive example, characteristic dimension 52 may include a pitch, or characteristic periodicity, of at least a portion of front side electrical pads 42 and/or back side electrical pads 46.

When contact structures 104, 204 include a plurality of electrical contacts 110, 210 arranged in a periodic array, the plurality of electrical contacts may include one or more active electrical contacts 90 that are in electrical communication with an electrical pad, as well as one or more inactive electrical contacts 94 that are not in electrical communication with an electrical pad. When contact structures 104, 204 include active electrical contacts 90 and inactive electrical contacts 94, test assembly 20, test system 10, and/or test signal generation and analysis system 60 of FIG. 1 may be configured to map, locate, and/or otherwise differentiate active electrical contacts 90 and/or inactive electrical contacts 94. As an illustrative, non-exclusive example, this mapping may include supplying a test signal to each electrical contact 110, 210 and detecting the presence and/or absence of a resultant signal associated with supply of the test signal to the electrical contact.

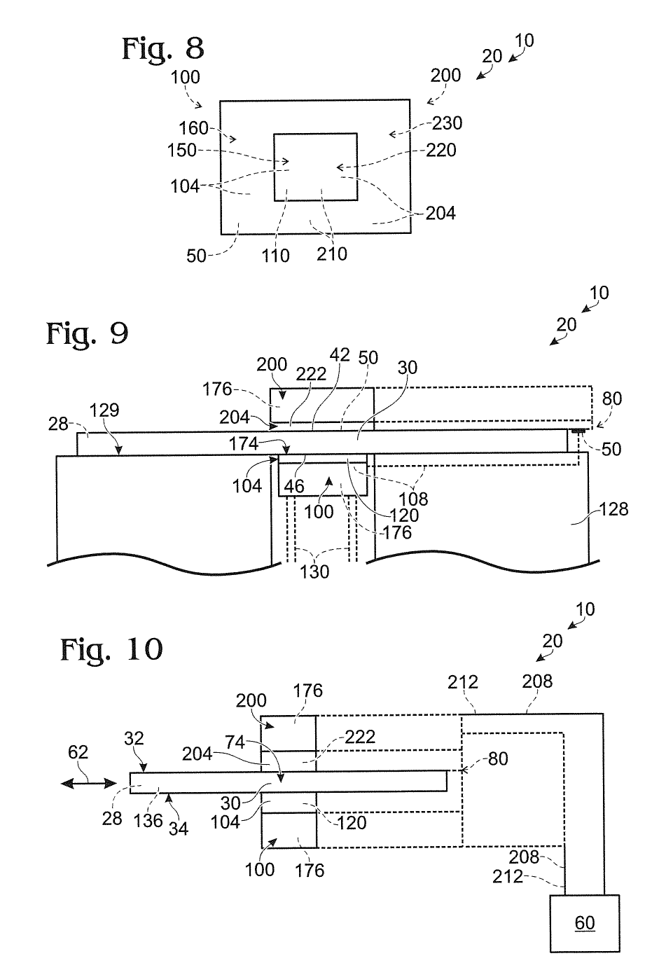

As discussed in more detail herein, test fixture 100 optionally may include at least a first test fixture region 150 and a second test fixture region 160. Similarly, and as also discussed in more detail herein, probe head 200 optionally also may include at least a first probe head region 220 and a second probe head region 230. This is shown in FIG. 8, which provides a schematic representation of an illustrative, non-exclusive example of a top and/or bottom view of a suitable layout of test fixture 100 and/or probe head 200. In FIG. 8, first test fixture region 150 is surrounded by and/or forms a concentric structure with second test fixture region 160. Additionally or alternatively, first probe head region 220 is surrounded by and/or forms a concentric structure with second probe head region 230. It is within the scope of the present disclosure that the second test fixture region and/or the second probe head region may only partially and/or only substantially surround the first test fixture region and/or the first probe head region, respectively.

When test fixture 100 includes first test fixture region 150 and second test fixture region 160, first test fixture region 150 may include a contacting structure 104, such as a plurality of electrical contacts 110, that is configured to form an electrical connection between test fixture 100 and a plurality of back side electrical pads of a DUT. In addition, second test fixture region 160 may include a contacting structure 104, such as a plurality of auxiliary pads 50, that is configured to form an electrical connection between test fixture 100 and probe head 200.

Additionally or alternatively, when probe head 200 includes first probe head region 220 and second probe head region 230, first probe head region 220 may include a contacting structure 204, such as a plurality of electrical contacts 210, that is configured to form an electrical connection between probe head 200 and a plurality of front side electrical pads of DUT 30. In addition, second probe head region 230 may include a contacting structure 204, such as a plurality of electrical contacts 210, that is configured to form an electrical connection between probe head 200 and test fixture 100, such as to a plurality of auxiliary pads thereof.

When probe head 200 includes first probe head region 220 and second probe head region 230, the first probe head region may include and/or be in electrical communication with a first contact engine that is configured to control the planarity and/or compliance of the first probe head region as it contacts the DUT. Similarly, the second probe head region may include and/or be in electrical communication with a second contact engine that is configured to control the planarity and/or compliance of the second probe head region when initiating and/or maintaining contact with the auxiliary pads of the second test fixture region. Illustrative, non-exclusive examples of controlling the planarity and/or compliance of the first probe head region and/or the second probe head region are discussed in more detail herein.

When utilized, first probe head region 220 and second probe head region 230 may be at least substantially coplanar. Alternatively, first probe head region 220 and second probe head region 230 may be in different planes, including different parallel planes or different intersecting planes. It is also within the scope of the present disclosure that adjusting the planarity and/or compliance of the first probe head region may include adjusting the planarity and/or compliance of the first probe head region independent of the planarity and/or compliance of the second probe head region. Similarly, the first contact engine and the second contact engine, when present, may include independent contact engines. However, it is also within the scope of the present disclosure that the first contact engine and the second contact engine may include the same contact engine and/or that the separate contact engines may not operate independently.

While discussed herein in the context of a probe head that may include first and second probe head regions that are configured to contact the DUT and the auxiliary pads of test fixture 100, it is within the scope of the present disclosure that the first probe head region may be configured to form an electrical connection with a first DUT, that the second probe head region may be configured to form an electrical connection with a second DUT, and/or that the probe head may include a plurality of probe head regions. Similarly, it is within the scope of the present disclosure that test fixture 100 may include a plurality of test fixture regions. It is also within the scope of the present disclosure that first test fixture region 150 and second test fixture region 160, and/or that first probe head region 220 and second probe head region 230, may include different contacting structures 104, 204, such as different electrical contacts 110, 210 and/or that they may include similar contacting structures 104, 204, such as similar electrical contacts 110, 210.

FIG. 9 provides an illustrative, non-exclusive example of a test assembly 20 that includes a test fixture 100, a probe head 200, and a wafer chuck 128. As discussed in more detail herein, test systems 10 and/or test assemblies 20 according to the present disclosure may (but are not required in all embodiments to) include at least a first contacting structure, such as contacting structure 104 of test fixture 100, which includes a compliant structure 120 and a second contacting structure, such as contacting structure 204 of probe head 200, which includes a compliant structure 222. As also discussed in more detail herein, test fixture 100 optionally may be, be located on, and/or form a portion of wafer chuck 128, which is configured to hold a semiconductor wafer during testing operations. In FIG. 9, wafer chuck 128 may hold a semiconductor wafer 28, or portion thereof, that includes DUT 30. Wafer chuck 128 may be configured to form a flat, or at least substantially flat, surface, or substrate, that is configured to hold and/or restrain semiconductor wafer 28 and/or move, or translate, semiconductor wafer 28 with respect to test fixture 100 and/or probe head 200 in a plane that is parallel to, or at least substantially parallel to, an upper surface of the semiconductor wafer.

Test fixture 100 may be configured to be moved into and/or out of electrical contact with DUT 30 without damage to, irreversible deformation of, and/or significant deformation of semiconductor wafer 28, such as by translating test fixture 100 up and down in a vertical direction. As shown in FIG. 9, test fixture 100 and/or wafer chuck 128 may include or be in contact with one or more down stops 130 that are configured to control and/or limit a translation of test fixture 100 in the downward direction. When utilized, down stops 130, together with compliant structure 120, may decrease, or otherwise limit, the deformation of semiconductor wafer 28 when it is in electrical contact with wafer chuck 128, test fixture 100, and/or probe head 200.

As discussed in more detail herein, compliant structure 222 of probe head 200 may include a different compliance than a compliance of compliant structure 120 of test fixture 100. As an illustrative, non-exclusive example, the compliance of compliant structure 120 may be less than the compliance of compliant structure 222, thereby limiting the deformation of semiconductor wafer 28 by maintaining a top surface 174 of test fixture 100, or compliant structure 120 thereof, to be at least substantially coplanar with a top surface 129 of wafer chuck 128. Similarly, the higher compliance of compliant structure 222 may provide for reliable and/or reproducible electrical contact among semiconductor wafer 28, test fixture 100, and probe head 200, while largely focusing deformation to within compliant structure 222.

As discussed in more detail herein, test fixture 100 may electrically connect at least a first 56 back side electrical pad 46 of DUT 30 to at least a second 58 back side electrical pad 46 of DUT 30. Under these conditions, and as also discussed in more detail herein, a portion of front side electrical pads 42 of DUT 30 also may function as, and/or be, auxiliary pads 50. Additionally or alternatively, and as shown in dashed lines in FIG. 9, test fixture 100 and/or wafer chuck 128 may include and/or be in electrical communication, via electrical conduit 108, with one or more auxiliary pads 50 that may be located outside an outer circumference of semiconductor wafer 28 and may be configured to form an electrical connection between one or more back side electrical pads 46 of DUT 30 and probe head 200 in test fixture-probe head contacting region 80.

Similar to the preceding discussion of first probe head region 220 and second probe head region 230, test fixture 100 and probe head 200 optionally may include and/or be in communication with separate and/or independent contact engines that are configured to control the contact between test fixture 100 and semiconductor wafer 28, between semiconductor wafer 28 and probe head 200, and/or between test fixture 100 and probe head 200. Although not required, the use of separate contact engines may provide for independent control of at least planarity and/or compliance of test fixture 100 and/or probe head 200 with respect to semiconductor wafer 28.

FIG. 10 provides yet another illustrative, non-exclusive example of a test system 10 including a test assembly 20 according to the present disclosure. As discussed in more detail herein, test system 10 may include at least one test signal generation and analysis system 60 that is configured to provide a test signal 208 to DUT 30, to receive a resultant signal 212 from DUT 30, and/or to control the operation of at least a portion of test system 10 and/or test assembly 20. As an illustrative, non-exclusive example, test system 10 may include and/or be in communication with a translation structure 62 that is configured to translate DUT 30 with respect to test fixture 100 and/or probe head 200.

When DUT 30 forms a portion of and/or is located in a structure that includes a plurality of DUTs 30, such as semiconductor wafer 28 and/or die tray 136, translation structure 62 may move a first DUT into a testing location 74, test system 10 may electrically test the first DUT, and, subsequent to the electrically testing, translation structure 62 may move a second DUT into testing location 74. This may include moving the first DUT of the plurality of DUTs into the testing location, contacting a front side 32 of the first DUT with probe head 200, contacting a back side 34 of the first DUT with test fixture 100, performing the electrical testing, moving the probe head and the test fixture out of electrical contact with the DUT, and translating the second DUT of the plurality of DUT into the testing location.

As discussed in more detail herein, at least a portion of the front side electrical pads of DUT 30 also may function as, and/or be, auxiliary pads. Additionally or alternatively, a portion of test fixture 100 and/or probe head 200 may extend past an outer circumference of semiconductor wafer 28, thereby providing for direct contact between the probe head and the test fixture in test fixture-probe head contacting region 80. FIGS. 9 and 10 also illustrate that, as discussed in more detail herein, test fixture 100 and/or probe head 200 also may include and/or be in thermal communication with thermal management system 176.

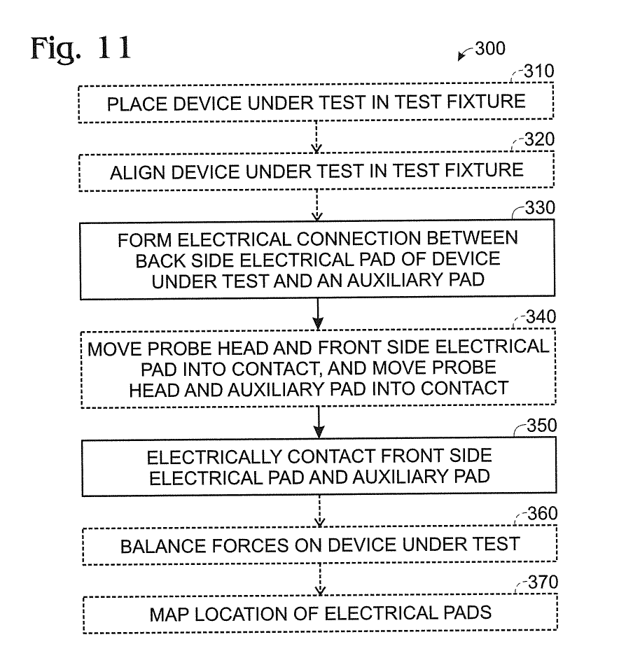

FIG. 11 is a flowchart depicting illustrative, non-exclusive examples of methods 300 according to the present disclosure of probing a DUT. Methods 300 optionally include placing the DUT in a test fixture at 310 and aligning the DUT within the test fixture at 320. Methods 300 include forming an electrical connection between a back side electrical pad of the DUT and an auxiliary pad at 330, and optionally include moving the probe head and the front side electrical pad into contact with one another and moving the probe head and the auxiliary pad into contact with one another at 340. Methods 300 further include electrically contacting the front side electrical pad and the auxiliary pad at 350, and optionally may include balancing forces applied to the DUT at 360 and/or mapping a location of one or more electrical pads of the DUT at 370.

Placing the DUT in a test fixture at 310 may include placing the DUT in any suitable test fixture that is configured to provide an electrical connection between one or more back side electrical pads of the DUT and one or more auxiliary pads. As an illustrative, non-exclusive example, this may include placing the DUT in any of the test fixtures disclosed herein. As another illustrative, non-exclusive example, this may include placing the DUT in a test fixture that includes and/or is in electrical communication with any of the auxiliary pads 50 disclosed herein.

Aligning the device under test in the test fixture at 320 may include the use of any suitable alignment structure to align the DUT to within a threshold tolerance of a desired location within the test fixture. This may include the use of any of the alignment structures disclosed herein and may include aligning to any suitable threshold tolerance, including the illustrative, non-exclusive examples of threshold tolerances disclosed herein.

Forming an electrical connection between the back side electrical pad of the device under test and the auxiliary pad at 330 may include the use of any suitable structure to place the back side electrical pad into electrical communication with the auxiliary pad, including the illustrative, non-exclusive examples of electrical conduits disclosed herein. It is within the scope of the present disclosure that, as discussed in more detail herein, the auxiliary pad may face a different direction than the back side electrical pad, including a direction that is similar to, the same as, and/or within a threshold angle of a direction of the front side electrical pad.

Moving the probe head and the front side electrical pad into contact and moving the probe head and the auxiliary pad into contact at 340 may include physically and/or electrically contacting the front side electrical pad with the probe head and physically and/or electrically contacting the auxiliary pad with the probe head. This may include moving the probe head and the front side electrical pad and moving the probe head and the auxiliary pad into a physically touching, a physically contacting, and/or an electrically contacting relationship with one another. As used herein, an electrically contacting relationship includes an electrically conductive relationship, as well as an inductively and/or capacitively coupled relationship.

Electrically contacting the front side electrical pad and the auxiliary pad at 350 may include electrically contacting both the front side electrical pad and the auxiliary pad from a direction that is generally opposed to the back side of the DUT, from at least substantially the same direction, and/or from the front side of the DUT. As an illustrative, non-exclusive example, the electrically contacting may include simultaneously contacting the front side electrical pad and the auxiliary pad.

Additionally or alternatively, the electrically contacting also may include decreasing a distance between a contacting structure, which is configured to electrically contact the front side electrical pad and the auxiliary pad, and the front side of the device under test, the front side electrical pad, and/or the auxiliary pad. Illustrative, non-exclusive examples of the decreasing may include moving the contacting structure and/or a probe head that includes the contacting structure toward the device under test and/or the auxiliary pad and/or moving the device under and/or the auxiliary pad toward the contacting structure and/or the probe head.

As used herein, “simultaneously contacting” may include initiating contact with the front side electrical pad and the auxiliary pad at the same, or at least substantially the same, time, contacting both the front side electrical pad and the auxiliary pad with a probe head, contacting both the front side electrical pad and the auxiliary pad with a single probe head, providing a test signal to at least one of the front side electrical pad and the auxiliary pad and receiving a resultant signal from the other of the front side electrical pad and the auxiliary pad, maintaining electrical contact between the probe head and the front side electrical pad simultaneously with maintaining electrical contact between the probe head and the auxiliary pad, initiating contact between the probe head and the front side electrical pad simultaneous with initiating contact between the probe head and the auxiliary pad, and/or moving the probe head and the front side electrical pad into contact with one another and moving the probe head and the auxiliary pad into contact with one another, wherein both the front side electrical pad and the auxiliary pad are contacted during the moving.

Balancing forces on the DUT at 360, when utilized, may include the use of one or more force balance tips to apply a force to at least one of the front side of the DUT and the back side of the DUT in order to balance a force that is applied to the other of the front side of the DUT and the back side of the DUT. It is within the scope of the present disclosure that the balancing may include decreasing, minimizing, and/or at least substantially eliminating a deformation of the DUT due to the application of force to the DUT by one or more of the contacting structures disclosed herein.

Mapping a location of the electrical pads at 370, when utilized, may include determining, storing, and/or otherwise obtaining an absolute and/or relative location of the back side electrical pad based, at least in part, on an electrical signal that may be supplied to the back side electrical pad, an optical image of the back side electrical pad, and/or other data related to the location of the back side electrical pad. As an illustrative, non-exclusive example, and as discussed in more detail herein, it is within the scope of the present disclosure that the test fixture may include a plurality of electrical contacts that are configured in a periodic array, and the mapping may include supplying a test signal to at least a first portion of the plurality of electrical contacts and detecting the presence and/or absence of the test signal in a second portion of the plurality of electrical contacts, in the auxiliary pad, and/or in the front side electrical pad.

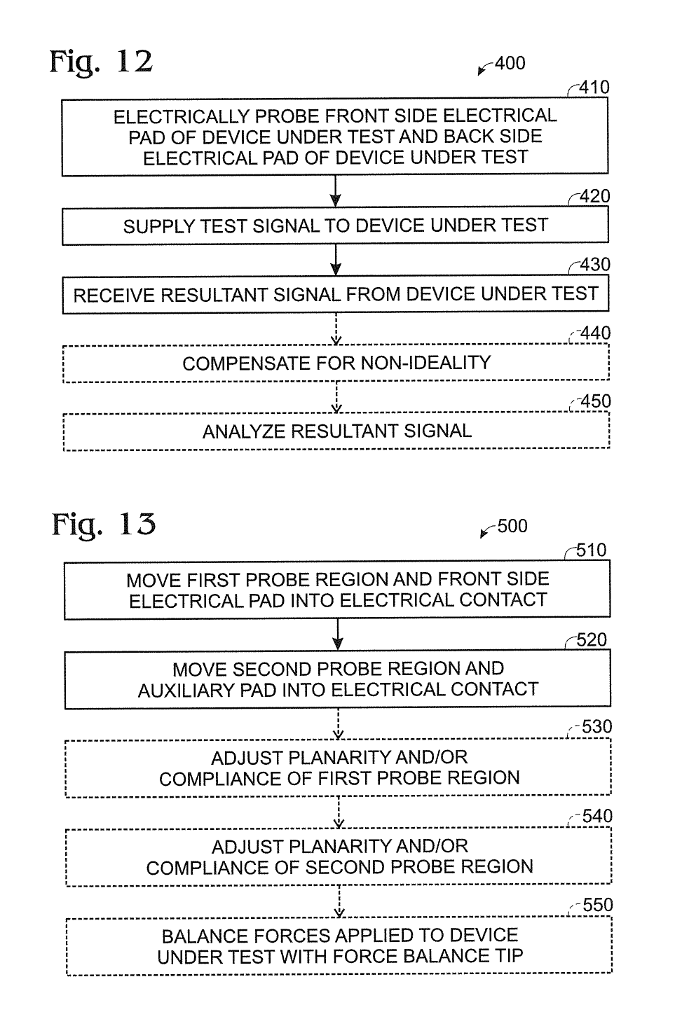

FIG. 12 is a flowchart depicting illustrative, non-exclusive examples of methods 400 according to the present disclosure of testing a DUT. These methods include electrically probing a front side electrical pad of the DUT and a back side electrical pad of the DUT at 410, supplying a test signal to the DUT at 420, and receiving a resultant signal from the DUT at 430. These methods optionally may include compensating for non-ideality at 440 and/or analyzing the resultant signal at 450.

Electrically probing the front side electrical pad of the DUT and the back side electrical pad of the DUT at 410 may include forming an electrical connection between the back side electrical pad and an auxiliary pad and electrically contacting the front side electrical pad and the auxiliary pad from a single side of the DUT. As an illustrative, non-exclusive example, this may include the use of any of the methods 300 discussed in more detail herein.

Supplying the test signal to the DUT at 420 may include supplying any suitable test signal to any suitable portion of the DUT and/or the test assembly using any suitable signal generator. Illustrative, non-exclusive examples of test signals according to the present disclosure are discussed in more detail herein. Similarly, illustrative, non-exclusive examples of signal generators according to the present disclosure also are discussed in more detail herein.

Receiving the resultant signal from the DUT at 430 may include receiving any suitable resultant signal from any suitable portion of the DUT and/or the test assembly using any suitable electrical conduit and/or signal analyzer. Illustrative, non-exclusive examples of resultant signals, electrical conduits, and/or signal analyzers that may be utilized with the systems and methods according to the present disclosure are discussed in more detail herein.

Compensating for non-ideality at 440, when utilized, may include the use of any suitable structure and/or algorithm to change, modify, and/or adjust the resultant signal based upon one or more electrical properties of the test system, the test assembly, the probe head, and/or the test fixture. As an illustrative, non-exclusive example, the compensating may include modifying the resultant signal through the use of electrical and/or software filters based, at least in part, on the electrical properties of the test system. Other illustrative, non-exclusive examples of compensating according to the present disclosure are discussed in more detail herein.

Analyzing the resultant signal at 450, when utilized, may include the use of any suitable hardware and/or algorithm to determine one or more characteristics of the DUT based, at least in part, on the resultant signal, the test signal, a comparison of the resultant signal to the test signal, the DUT, and/or a structure of the electronic devices that comprise the DUT. It is within the scope of the present disclosure that the analyzing may include determining the continuity of a portion of the DUT, testing for open circuits within a portion of the DUT, testing for short circuits within a portion of the DUT, and/or determining the performance of a portion of the DUT. Additional illustrative, non-exclusive examples of the analyzing are discussed in more detail herein.

FIG. 13 is a flowchart depicting illustrative, non-exclusive examples of methods 500 according to the present disclosure of electrically contacting a DUT. The methods include moving a first probe (or probe head or region of a probe head) and a front side electrical pad into electrical contact at 510, and moving a second probe (or probe head or region of a probe head) and an auxiliary pad into electrical contact at 520. The methods also may include adjusting a planarity and/or a compliance of the first probe head region at 530, adjusting a planarity and/or a compliance of the second probe head region at 540, and/or balancing the forces applied to the device under test with a force balance tip at 550.

Moving the first probe head region and the front side electrical pad into electrical contact at 510 and/or moving the second probe head region and the auxiliary pad into electrical contact at 520 may include moving a probe head, which includes the first probe head region and the second probe head region, and an assembly of a test fixture and a DUT, which includes the front side electrical pad and the auxiliary pad, into electrical contact with one another. This moving may include decreasing a distance between the first probe head region and the front side electrical pad concurrently with decreasing a distance between the second probe head region and the auxiliary pad, moving the first probe head region concurrently with moving the second probe head region, moving the assembly of the test fixture and the DUT toward the first probe head region and the second probe head region, and/or concurrently contacting a first contacting tip of the first probe head region with the front side electrical pad and a second contacting tip of the second probe head region with the auxiliary pad.

Adjusting the planarity and/or compliance of the first probe head region at 530 may include adjusting an orientation of the first probe head region with respect to the front side electrical contact and/or adjusting a force that is applied to the DUT and/or the front side electrical contact by the first probe head region based, at least in part, on a variable associated with the first probe head region. Similarly, adjusting the planarity and/or compliance of the second probe head region at 540 may include adjusting an orientation of the second probe head region with respect to the auxiliary pad and/or adjusting a force that is applied to the test fixture and/or the auxiliary pad by the second probe head region based, at least in part, on a variable associated with the second probe head region. Illustrative, non-exclusive examples of variables associated with the first and/or second probe head region are discussed in more detail herein. Similarly, illustrative, non-exclusive examples of adjusting the planarity and/or compliance of the first probe head region and/or the second probe head region are discussed in more detail herein.

Balancing forces applied to the DUT with a force balance tip at 550 may include the use of a force balance tip to decrease, minimize, and/or at least substantially eliminate a deformation of the DUT due to contact between the DUT and the probe head and/or due to contact between the DUT and the test fixture. Illustrative, non-exclusive examples of balancing forces are discussed in more detail herein.

Several of the illustrative, non-exclusive examples of DUT 30 disclosed herein have been discussed with reference to DUT 30 including and/or forming a portion of a semiconductor device and/or a semiconductor wafer. However, it is within the scope of the present disclosure that DUT 30 may include, be formed on, and/or form a portion of any suitable substrate and/or substrate material. Additionally or alternatively, it is also within the scope of the present disclosure that semiconductor wafer 28 also may be referred to as substrate 28. As used herein, the term “substrate” may refer to any suitable base material and/or surface upon which an electronic device may be fabricated, housed, located, supported, formed, utilized, and/or tested.

With reference to FIG. 1, test fixture 100 and/or probe head 200 may be configured to form, provide, and/or otherwise produce any suitable communication linkage 102, 202 between test fixture 100 and DUT 30, between probe head 200 and DUT 30, and/or between test fixture 100 and probe head 200. Thus, while the illustrative, non-exclusive examples disclosed herein are discussed in the context of electrical communication, electrical contacts, and/or electrical connections among these structures, such as through the use of any suitable electrically conductive, capacitively coupled, and/or inductively coupled interface, it is within the scope of the present disclosure that this communication linkage may, additionally or alternatively, be and/or include any suitable optical and/or wireless communication linkage.

As an illustrative, non-exclusive example, it is within the scope of the present disclosure that DUT 30 also may include, contain, form a portion of, be operatively attached to, and/or be in electrical and/or optical communication with one or more optical devices and/or that electronic devices 38 also may, additionally or alternatively, be, include, and/or be referred to as optical devices 38. As an illustrative, non-exclusive example, DUT 30 may include one or more electronic devices. As another illustrative, non-exclusive example, DUT 30 may include one or more optical devices. As yet another illustrative, non-exclusive example, DUT 30 may include one or more electronic devices and one or more optical devices.

When DUT 30 includes optical devices, it is within the scope of the present disclosure that the optical devices may form a portion of, function cooperatively with, be integral with, and/or be in communication with the electronic devices. However, it is also within the scope of the present disclosure that the optical devices may be separate from, may be located in different regions from, may be distinct from, may not function cooperatively with, and/or may not be in communication with the electronic devices.

When DUT 30 includes the optical devices, it is within the scope of the present disclosure that front side electrical pad(s) 42 also may be referred to as front side optical pad(s) 42 that may be configured to provide optical communication with the optical devices, and/or that back side electrical pad(s) 46 also may be referred to as back side optical pad(s) 46 that may be configured to provide optical communication with the optical devices. In addition, contacting structures 104, 204 may include one or more structures that are configured to provide optical communication with the optical pad(s) of DUT 30.

As an illustrative, non-exclusive example, contacting tip(s) 116, 216 also may include and/or be referred to as optically contacting tip(s) 116, 216 and/or electrical contacts 110, 210 also may include and/or be referred to as optical contacts 110, 210. These optical contacting tips and/or optical contacts may include, contain, and/or be in communication with one or more optical emitters and/or optical detectors, or transducers, configured to provide and/or receive an optical signal, respectively. Similarly, electrical conduit 108 of test fixture 100 also may include or be referred to as optical conduit 108 and auxiliary pads 50 also may include and/or be referred to as optical auxiliary pads 50. In addition, the optical conduit may be configured to convey an optical signal between one or more back side optical pad(s) and one or more optical auxiliary pad(s).

As another illustrative, non-exclusive example, it is within the scope of the present disclosure that front side electrical pad(s) 42, back side electrical pad(s) 46, and/or auxiliary pad(s) 50 may include, contain, and/or be in communication with one or more wireless transmitters and/or wireless receivers that are configured to transfer information among test fixture 100, probe head 200, and/or DUT 30 without the need for direct, physical contact between test fixture 100, probe head 200, and/or DUT 30. As an illustrative, non-exclusive example, at least a first component of test fixture 100, probe head 200, and/or DUT 30 may include and/or be in communication with a wireless transmitter, and at least a second component of test fixture 100, probe head 200, and/or DUT 30 may include and/or be in communication with a wireless receiver, or antenna. As another illustrative, non-exclusive example, the wireless transmitter of the first component may wirelessly transfer a wireless signal to the wireless receiver of the second component.

When the first component includes the wireless transmitter and the second component includes the wireless receiver, it is within the scope of the present disclosure that a transmission distance between the wireless transmitter and the wireless receiver may be less than a threshold transmission distance. Illustrative, non-exclusive examples of threshold transmission distances according to the present disclosure include transmission distances of less than 1000 micrometers, less than 500 micrometers, less than 400 micrometers, less than 300 micrometers, less than 200 micrometers, less than 100 micrometers, less than 50 micrometers, less than 25 micrometers, less than 10 micrometers, less than 5 micrometers, or less than 1 micrometer. Illustrative, non-exclusive examples of wireless signals according to the present disclosure include any suitable test signal, resultant signal, data stream, radio frequency signal, microwave frequency signal, and/or electromagnetic signal.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “plurality” means two or more. Thus, a system that includes a plurality of components may include two or more components. By two or more, it is meant that there are at least two components but that there is no theoretical limitation on the maximum number of components. As an illustrative, non-exclusive example, a system that includes a plurality of components may include 2, more than 2, more than 3, more than 4, more than 5, more than 10, more than 20, more than 25, more than 50, more than 100, more than 250, more than 500, more than 1,000, more than 5,000, more than 10,000, more than 25,000, more than 50,000, etc. components.

At least in the context of DUT 30, a plurality of electronic devices 38 may include two or more such electronic devices, including any of the illustrative, non-exclusive examples presented above, as well as more than 100,000, more than 250,000, more than 500,000, more than 1,000,000, more than 5,000,000, more than 10,000,000, more than 25,000,000, more than 50,000,000, more than 100,000,000, more than 250,000,000, more than 500,000,000, more than 1,000,000,000, more than 2,500,000,000, more than 5,000,000,000, or more than 10,000,000,000 electronic devices 38. Thus, and while front side electrical pads 42 and/or back side electrical pads 46 often may be in electrical communication with more than one electronic device 38, it is within the scope of the present disclosure that, as illustrative, non-exclusive examples, a plurality of front side electrical pads 42, a plurality of back side electrical pads 46, a plurality of auxiliary pads 50, a plurality of electrical conduits 108, a plurality of contacting tips 116, 216, a plurality of electrical contacts 110, 210, and/or a plurality of communication linkages 102, 202 may refer to two or more of these structures, optionally including any of the illustrative, non-exclusive examples presented above.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” may mean A alone, B alone, C alone, A and B together, A and C together, B and C together, A, B and C together, and optionally any of the above in combination with at least one other entity.

In the event that any patents, patent applications, or other references are incorporated by reference herein and define a term in a manner or are otherwise inconsistent with either the non-incorporated portion of the present disclosure or with any of the other incorporated references, the non-incorporated portion of the present disclosure shall control, and the term or incorporated disclosure therein shall only control with respect to the reference in which the term is defined and/or the incorporated disclosure was originally present.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

Illustrative, non-exclusive examples of systems, devices, and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A method of electrically probing a front side and a back side of a device under test, wherein the front side includes a front side electrical pad, and further wherein the back side includes a back side electrical pad, the method comprising:

step for routing the back side electrical pad to an auxiliary pad; and

step for electrically contacting the front side electrical pad and the auxiliary pad.

A2. The method of paragraph A1, wherein the step for routing includes forming an electrical connection between the back side electrical pad and an auxiliary pad.

A3. The method of any of paragraphs A1-A2, wherein the step for electrically contacting includes electrically contacting the auxiliary pad and the front side electrical pad from one or more of a direction generally opposed to the back side of the device under test, the front side of the device under test, and at least substantially the same direction.

B1. A method of electrically probing a front side and a back side of a device under test, wherein the front side includes a front side electrical pad, and further wherein the back side includes a back side electrical pad, the method comprising:

forming an electrical connection between the back side electrical pad and an auxiliary pad that faces in a different direction that the back side electrical pad, optionally wherein the front side electrical pad faces in a front side direction, the back side electrical pad faces in a back side direction, and the auxiliary pad faces in an auxiliary pad direction, and further optionally wherein the auxiliary pad direction is at least one of generally opposed to the back side direction, different from the back side direction, generally parallel to the front side direction, and/or the same as the front side direction; and

electrically contacting the front side electrical pad and the auxiliary pad:

(i) from one or more of a direction generally opposed to the back side of the device under test, the front side of the device under test, and at least substantially the same direction; and/or

(ii) with a contacting structure, optionally by decreasing a distance between the contacting structure and one or more of the front side of the device under test, the front side electrical pad, and the auxiliary pad.

C1. The method of any of paragraphs A1-B1, wherein the electrically contacting includes simultaneously contacting the front side electrical pad and the auxiliary pad.

C2. The method of paragraph C1, wherein the simultaneously contacting includes providing a test signal to at least one of the front side electrical pad and the auxiliary pad and receiving a resultant signal from the other of the front side electrical pad and the auxiliary pad.

C3. The method of any of paragraphs A3-C2, wherein the electrically contacting includes contacting, and optionally simultaneously contacting, the auxiliary pad and the front side electrical pad with a probe head that optionally includes the contacting structure, optionally wherein the probe head includes a thermal management structure, optionally wherein the method further includes controlling a temperature of at least a portion of at least one of the probe head and the device under test using the thermal management structure, and further optionally wherein the controlling includes at least one of maintaining the temperature near a target temperature and maintaining the temperature between predetermined upper and lower threshold temperatures.

C4. The method of paragraph C3, wherein the simultaneously contacting includes maintaining electrical contact between the probe head and the front side electrical pad simultaneously with maintaining electrical contact between the probe head and the auxiliary pad.

C5. The method of any of paragraphs C3-C4, wherein the simultaneously contacting includes initiating contact between the probe head and the front side electrical pad simultaneously with initiating contact between the probe head and the auxiliary pad.

C6. The method of any of paragraphs C3-C5, wherein the method includes moving the probe head and the front side electrical pad into contact with each other, wherein the method includes moving the probe head and the auxiliary pad into contact with each other, and optionally wherein the moving includes simultaneously contacting both the front side electrical pad and the auxiliary pad with the probe head during the moving.

C7. The method of any of paragraphs A1-C6, wherein the front side is at least substantially opposed to the back side.

C8. The method of any of paragraphs A1-C7, wherein the device under test includes an at least substantially planar device under test, and optionally wherein the device under test is fabricated on a substrate, is operatively attached to a substrate, and/or forms a portion of a substrate.

C9. The method of any of paragraphs A1-C8, wherein the front side forms a first major surface of the device under test, wherein the back side forms a second major surface of the device under test, wherein the device under test includes at least a first minor surface, and further wherein a surface area of the first major surface and the second major surface forms a majority of a surface area of the device under test, optionally wherein the surface area of the first major surface and the second major surface forms at least 50%, at least 60%, at least 70%, at least 80%, at least 90%, at least 95%, at least 97%, at least 98%, at least 99%, at least 99.5%, or at least 99.9% of the surface area of the device under test.

C10. The method of any of paragraphs C3-C9, wherein the electrically contacting includes electrically contacting the front side electrical pad with a first contacting tip of the probe head and electrically contacting the auxiliary pad with a second contacting tip of the probe head.

C11. The method of paragraph C10, wherein the first contacting tip and the second contacting tip form a portion of a single probe head.

C12. The method of any of paragraphs C10-C11, wherein the first contacting tip and the second contacting tip face in at least substantially the same direction.

C13. The method of any of paragraphs C10-C12, wherein the electrically contacting includes establishing contact between the first contacting tip and the front side electrical pad and between the second contacting tip and the auxiliary pad, and optionally wherein the electrically contacting includes moving the first contacting tip and the front side electrical pad into contact with each other and moving the second contacting tip and the auxiliary pad into contact with each other.

C14. The method of paragraph C13, wherein the contact includes at least one of, and optionally both of, physical contact and electrical contact.

C15. The method of any of paragraphs C3-C14, wherein the front side defines a front side surface normal direction, and further wherein the electrically contacting includes at least one of moving the probe head in a direction that is at least substantially opposed to the front side surface normal direction, moving the device under test in a direction that is at least substantially the same as the front side surface normal direction, and moving the auxiliary pad in a direction that is at least substantially the same as the front side surface normal direction.

C16. The method of any of paragraphs C3-C15, wherein the back side defines a back side surface normal direction, and further wherein the electrically contacting includes at least one of moving the probe head in a direction that is at least substantially the same as the back side surface normal direction, moving the device under test in a direction that is at least substantially opposed to the back side surface normal direction, and moving the auxiliary pad in a direction that is at least substantially opposed to the back side surface normal direction.

C17. The method of any of paragraphs C3-C16, wherein the electrically contacting includes electrically contacting the front side electrical pad and the auxiliary pad with a probe head, and optionally wherein the single probe head includes a plurality of contacting tips.

C18. The method of any of paragraphs C3-C17, wherein the probe head includes a probe head force balance tip configured to apply a force to the device under test, and further wherein the method includes balancing a force applied to the back side of the device under test with a force applied to the front side of the device under test by the probe head force balance tip, and optionally wherein the force applied to the back side of the device under test is applied during the forming an electrical connection.

C19. The method of any of paragraphs A2-C18, wherein the forming an electrical connection between the back side electrical pad and the auxiliary pad includes placing the device under test in a test fixture configured to provide the electrical connection between the back side electrical pad and the auxiliary pad, optionally wherein the test fixture includes a thermal management structure, optionally wherein the method further includes controlling a temperature of at least a portion of at least one of the test fixture and the device under test using the thermal management structure, and further optionally wherein the controlling includes at least one of maintaining the temperature near a target temperature and maintaining the temperature between predetermined upper and lower threshold temperatures.

C20. The method of paragraph C19, wherein the auxiliary pad forms a portion of the test fixture.

C21. The method of any of paragraphs C19-C20, wherein the test fixture includes at least one of a socket, a wafer, a semiconductor wafer, a silicon wafer, a carrier wafer, a smart wafer, a translator wafer, a handling wafer, a chuck, a die seat, a tray, and a die tray, and optionally wherein the test fixture includes at least one of an electrical structure, a semiconductor device, a passive electronic component, a resistor, a capacitor, an inductor, an electrical conductor, a via, a through silicon via, a metal line, an interposer, a space transformer, an active electronic component, a transistor, a processor circuit, a memory circuit, an integrated circuit, an application specific integrated circuit, a logic circuit, a sensor circuit, a system on a chip, a power supply circuit, a microelectronic device, a microprocessor, and a power control circuit.

C22. The method of any of paragraphs C19-C21, wherein the test fixture includes an interface region configured to provide the electrical connection between the back side electrical pad and the test fixture, and further wherein the forming an electrical connection includes forming the electrical connection with the interface region.

C23. The method of paragraph C22, wherein the interface region includes at least one of a conductive material, a polymer, a conductive polymer, an anisotropically conductive polymer, a metal, a conductive grid, a conductive sheet, and a patterned conductive surface.

C24. The method of any of paragraphs C19-C23, wherein the test fixture includes a test fixture contacting tip configured to contact the back side electrical pad, and further wherein the forming an electrical connection includes contacting the back side electrical pad with the test fixture contacting tip.

C25. The method of any of paragraphs C19-C24, wherein the test fixture includes a test fixture force balance tip configured to apply a force to the device under test, and further wherein the method includes balancing a force applied to the front side of the device under test by the probe head with a force applied to the back side of the device under test by the test fixture force balance tip.

C26. The method of any of paragraphs C19-C25, wherein the method further includes aligning the device under test within the test fixture.

C27. The method of paragraph C26, wherein the aligning includes aligning the device under test relative to a reference structure, and optionally wherein the reference structure includes at least one of an edge of the device under test, a corner of the device under test, an electrical structure on the device under test, an electrical pad, a through silicon via, an optically visible structure on the device under test, and a lithographically defined feature.

C28. The method of any of paragraphs C26-C27, wherein the back side electrical pad includes a characteristic dimension, and further wherein the aligning includes aligning the device under test within the test fixture to within a threshold proportion of the characteristic dimension.

C29. The method of paragraph C28, wherein the threshold proportion is less than 50%, optionally including less than 40%, less than 30%, less than 25%, less than 20%, less than 15%, less than 10%, less than 5%, less than 4%, less than 3%, less than 2%, or less than 1% of the characteristic dimension.

C30. The method of any of paragraphs C28-C29, wherein the characteristic dimension is less than 250 micrometers, optionally including characteristic dimensions of less than 200 micrometers, less than 150 micrometers, less than 125 micrometers, less than 100 micrometers, less than 90 micrometers, less than 80 micrometers, less than 70 micrometers, less than 60 micrometers, less than 50 micrometers, less than 40 micrometers, less than 30 micrometers, less than 20 micrometers, less than 15 micrometers, less than 10 micrometers, less than 5 micrometers, less than 4 micrometers, less than 3 micrometers, less than 2 micrometers, less than 1 micrometer, less than 0.75 micrometers, less than 0.5 micrometers, less than 0.25 micrometers, or less than 0.1 micrometer.

C31. The method of any of paragraphs A2-C30, wherein the back side includes a plurality of back side electrical pads.

C32. The method of paragraph C31, wherein the forming an electrical connection includes electrically connecting a portion of the plurality of back side electrical pads together, optionally wherein the portion includes a majority of the plurality of back side electrical pads, and still further optionally wherein the portion includes all of the plurality of back side electrical pads.

C33. The method of any of paragraphs C31-C32, wherein the forming an electrical connection includes electrically connecting selected ones of the plurality of back side electrical pads together.

C34. The method of any of paragraphs C31-C33, wherein the device under test includes a plurality of die, and further wherein the forming and electrical connection includes electrically connecting selected ones of the plurality of back side electrical pads of a first die of the plurality of die together with selected ones of the plurality of back side electrical pads of a second die of the plurality of die.

C35. The method of any of paragraphs C31-C34, wherein the auxiliary pad includes a plurality of auxiliary pads, and further wherein the forming an electrical connection includes forming an electrical connection between selected ones of the plurality of back side electrical pads and selected ones of the plurality of auxiliary pads.

C36. The method of paragraph C35, wherein the forming an electrical connection includes forming a discrete electrical connection between an individual back side electrical pad and an individual auxiliary pad.

C37. The method of any of paragraphs C31-C36, wherein the forming an electrical connection includes forming an electrical connection between the plurality of back side electrical pads and an individual auxiliary pad.

C38. The method of any of paragraphs C35-C37, wherein the forming an electrical connection includes forming an electrical connection between an individual back side electrical pad and the plurality of auxiliary pads.

C39. The method of any of paragraphs C35-C38, wherein the method includes receiving the device under test in a test fixture that includes a plurality of electrical contacts configured to align with a portion of the plurality of back side electrical pads, and further wherein the forming an electrical connection includes forming the electrical connection between the plurality of electrical contacts and the plurality of back side electrical pads.

C40. The method of paragraph C39, wherein the plurality of electrical contacts are configured in complementary locations to a corresponding location of at least a portion of the plurality of back side electrical pads.

C41. The method of paragraph C39, wherein the plurality of electrical contacts are configured in a periodic array, and optionally wherein a pitch of the periodic array is less than a characteristic dimension of the back side electrical pads, optionally wherein the pitch of the periodic array is less than 50% of the characteristic dimension of the back side electrical pads, and further optionally wherein the pitch of the periodic array is less than 40%, less than 30%, less than 25%, less than 20%, less than 15%, or less than 10% of the characteristic dimension of the back side electrical pads.

C42. The method of paragraph C41, wherein the method further includes electrically mapping a location of at least a portion of the plurality of back side electrical pads by supplying an electric current to at least a portion of the plurality of back side electrical pads.

C43. The method of any of paragraphs A3-C42, wherein the forming an electrical connection includes forming an electrical connection at a first electrical interface that includes a first compliance, and further wherein the electrically contacting includes electrically contacting at least one of the front side electrical pad and the auxiliary pad at a second electrical interface that includes a second compliance.

C44. The method of paragraph C43, wherein the first compliance is greater than the second compliance, wherein the method further includes deforming the first interface by a first amount and deforming the second interface by a second amount, and further wherein the first amount is greater than the second amount.

C45. The method of any of paragraphs C43-C44, wherein the first compliance is less than the second compliance, wherein the method further includes deforming the first interface by a first amount and deforming the second interface by a second amount, and further wherein the first amount is less than the second amount.

C46. The method of any of paragraphs A1-C45, wherein the device under test includes at least one of an electronic device, a semiconductor device, a transistor, a resistor, a capacitor, an inductor, an electrical conductor, a contact, a via, a through silicon via, a pad, a metal line, an interposer, a processor circuit, a memory circuit, an integrated circuit, an application specific integrated circuit, a logic circuit, a sensor circuit, a system on a chip, a power supply circuit, a space transformer, a microelectronic device, a microprocessor, a solar cell, and a power control circuit.

C47. The method of any of paragraphs A1-C46, wherein the device under test includes at least one of a portion of, a layer of, and a precursor to at least one of a stacked semiconductor device, a composite semiconductor device, a 2.5-dimensional integrated circuit, and a 3-dimensional integrated circuit.

C48. The method of any of paragraphs A1-C47, wherein the device under test includes at least one of a substrate, a silicon wafer, a gallium arsenide wafer, a semiconductor wafer, a portion of a semiconductor wafer, a plurality of die, an individual die, die that have not been singulated, a plurality of singulated die on adhesive tape, and a singulated die.

C49. The method of any of paragraphs A1-C48, wherein the device under test has a thickness of less than 1000 micrometers, optionally including a thickness of less than 500 micrometers, less than 250 micrometers, less than 100 micrometers, less than 90 micrometers, less than 80 micrometers, less than 70 micrometers, less than 60 micrometers, less than 50 micrometers, less than 40 micrometers, less than 30 micrometers, less than 20 micrometers, or less than 10 micrometers, and further optionally wherein the thickness includes an overall thickness of the device under test.

C50. The method of any of paragraphs A1-C49, wherein the device under test includes a plurality of die, wherein each of the plurality of die includes a back side electrical pad and a front side electrical pad, wherein the forming includes forming the electrical connection with a back side electrical pad of each of the plurality of die, and further wherein the electrically contacting includes electrically contacting a front side electrical pad of each of the plurality of die.

C51. The method of paragraph C50, wherein the method further includes providing a test signal to each of the plurality of die at least one of simultaneously and sequentially.

C52. The method of paragraph C50, wherein the method further includes providing a test signal to a first die of the plurality of die and receiving a resultant signal from a second die of the plurality of die.

C53. The method of paragraph C50, wherein the method further includes providing a test signal to a portion of the plurality of die and receiving a resultant signal from the auxiliary pad, and optionally wherein the auxiliary pad includes a plurality of auxiliary pads and the receiving includes receiving the resultant signal from a portion of the plurality of auxiliary pads.

C54. The method of any of paragraphs A2-C53, wherein the device under test includes a die, wherein the die is contained within a die tray that includes a test fixture, wherein the forming an electrical connection includes forming an electrical connection between a back side of the die and the test fixture, and further wherein the electrically contacting includes electrically contacting a front side of the die and a front side of at least one of the die tray and the test fixture.

C55. The method of any of paragraphs A1-C54, wherein the front side electrical pad forms a portion of the device under test.

C56. The method of any of paragraphs A1-C55, wherein the back side electrical pad forms a portion of the device under test.

C57. The method of any of paragraphs A1-C56, wherein the auxiliary pad forms a portion of the device under test.

C58. The method of any of paragraphs A1-C57, wherein the auxiliary pad forms a portion of a test fixture, and further wherein the test fixture does not form a portion of the device under test.

C59. The method of any of paragraphs A1-C58, wherein at least one of the front side electrical pad, the back side electrical pad, and the auxiliary pad includes an at least substantially flat contacting surface, and optionally where the front side electrical pad, the back side electrical pad, and the auxiliary pad each include an at least substantially flat contacting surface.

C60. The method of any of paragraphs A1-C59, wherein at least one of the front side electrical pad, the back side electrical pad, and the auxiliary pad includes at least one of a bond pad, a contact pad, and a landing pad.

C61. The method of any of paragraphs A1-C60, wherein the front side electrical pad defines a front side surface normal, the back side electrical pad defines a back side surface normal, and the auxiliary pad defines an auxiliary pad surface normal.

C62. The method of paragraph C61, wherein the back side surface normal is in a different direction from at least one of the front side surface normal and the auxiliary pad surface normal, and optionally wherein the back side surface normal is generally opposed to at least one of the front side surface normal and the auxiliary pad surface normal.

C63. The method of any of paragraphs C61-C62, wherein the front side surface normal is in at least substantially the same direction as the auxiliary pad surface normal.

C64. The method of any of paragraphs A1-C63, wherein the back side electrical pad faces in a different direction from at least one of the front side electrical pad and the auxiliary pad, and optionally wherein the back side electrical pad faces in an at least substantially opposite direction from at least one of the front side electrical pad and the auxiliary pad.

C65. The method of any of paragraphs A1-C64, wherein the front side electrical pad faces in at least substantially the same direction as the auxiliary pad.

C66. The method of any of paragraphs A1-C65, wherein the front side electrical pad is at least substantially coplanar with the auxiliary pad.

C67. The method of any of paragraphs A1-C65, wherein the front side electrical pad and the auxiliary pad are positioned at different distances away from a plane defined by the back side of the device under test.

C68. The method of any of paragraphs A1-C66, wherein the front side electrical pad and the auxiliary pad are positioned at least substantially the same distance away from a plane defined by the back side of the device under test.

C69. The method of any of paragraphs A1-C68, wherein the method further includes controlling a temperature of at least a portion of the device under test, and optionally wherein the controlling includes at least one of maintaining the temperature of the portion of the device under test near a target temperature and maintaining the temperature of the portion of the device under test between predetermined upper and lower threshold temperatures.

C70. The method of any of paragraphs A1-C69, wherein the forming includes initially forming a first electrical connection between a first back side electrical pad and a first auxiliary pad, and the method further includes subsequently forming a second electrical connection, wherein forming the second electrical connection includes at least one of forming the second electrical connection between the first back side electrical pad and a second auxiliary pad and forming the second electrical connection between a second back side electrical pad and the first auxiliary pad.

D1. A method of electrically testing a device under test, wherein the device under test includes a front side including a front side electrical pad and a back side including a back side electrical pad, the method comprising:

electrically probing the front side electrical pad of the device under test and the back side electrical pad of the device under test using the method of any of paragraphs A1-C70; and

supplying a test signal to at least one of the front side electrical pad and the back side electrical pad.

D2. The method of paragraph D1, wherein the method further includes receiving a resultant signal from the other of the front side electrical pad and the back side electrical pad.

D3. The method of paragraph D2, wherein the receiving includes receiving the resultant signal by at least one of a probe system and a spectrum analyzer.

D4. The method of any of paragraphs D2-D3, wherein the method further includes analyzing the resultant signal.

D5. The method of paragraph D4, wherein the analyzing includes compensating for a portion of the resultant signal that is due to the forming.

D6. The method of any of paragraphs D2-D5, wherein the resultant signal includes at least one of a DC resultant signal, an AC resultant signal, a radio frequency resultant signal, a microwave frequency resultant signal, and a null resultant signal.

D7. The method of any of paragraphs D1-D6, wherein the test signal includes at least one of a DC test signal, an AC test signal, a radio frequency test signal, and a microwave frequency test signal.

D8. The method of any of paragraphs D1-D7, wherein the supplying includes supplying the test signal from at least one of a probe system, a function generator, and a spectrum analyzer.

D9. The method of any of paragraphs D1-D8, wherein the method further includes testing for at least one of continuity, open circuits, and short circuits between the front side electrical pad and the back side electrical pad.

D10. The method of any of paragraphs D1-D9, wherein the method further includes electrically connecting a first through silicon via of the device under test to a second through silicon via of the device under test using a test fixture.

D11. The method of paragraph D10, wherein the method further includes testing for at least one of continuity, open circuits, and short circuits between the first through silicon via and the second through silicon via.

D12. The method of any of paragraphs D1-D11, wherein the method further includes electrically connecting a plurality of through silicon vias of the device under test using a test fixture.

D13. The method of paragraph D12, wherein the method further includes testing for at least one of continuity and open circuits between a first portion of the plurality of through silicon vias and a second portion of the plurality of through silicon vias.

D14. The method of any of paragraphs D2-D13, wherein the method further includes testing the functionality of an electronic device associated with the device under test, and optionally wherein the electronic device includes at least one of a semiconductor device, a transistor, a resistor, a capacitor, an inductor, a processor circuit, a memory circuit, an integrated circuit, an application specific integrated circuit, a logic circuit, a sensor circuit, a system on a chip, a microelectronic device, a microprocessor, a solar cell, a power supply circuit, and a power control circuit.

D15. The method of paragraph D14, wherein testing the functionality includes comparing the resultant signal to an expected resultant signal, and optionally wherein testing the functionality further includes determining if the resultant signal is between a first threshold value and a second threshold value.

D16. The method of any of paragraphs D14-D15, wherein the method further includes categorizing a performance of at least one of the electronic device and the device under test based at least in part on a value of the resultant signal.

D17. The method of any of paragraphs D1-D16 when depending from paragraph C70, wherein the test signal includes a first test signal, wherein the method includes forming the first electrical connection and supplying the first test signal, and further wherein the method includes forming the second electrical connection and supplying a second test signal.

E1. A method of electrically contacting a front side electrical pad and an auxiliary pad with a probe head, wherein the front side electrical pad is located on a front side of a device under test, and further wherein the auxiliary pad is in electrical communication with a back side electrical pad of the device under test and is located on a test fixture, the method comprising:

moving a first probe head region of the probe head and the front side electrical pad into electrical contact with each other, wherein the first probe head region includes a first contacting tip; and

moving a second probe head region of the probe head and the auxiliary pad into electrical contact with each other, wherein the second probe head region includes a second contacting tip.

E2. The method of paragraph E1, wherein the method further includes adjusting at least one of a planarity and a compliance of the first probe head region based at least in part on a variable associated with the first probe head region.

E3. The method of paragraph E2, wherein adjusting the planarity of the first probe head region includes adjusting an orientation of the first probe head region such that a plane defined by the first probe head region is at least substantially parallel to a plane defined by the front side of the device under test.

E4. The method of any of paragraphs E2-E3, wherein adjusting the compliance of the first probe head region includes adjusting a force that is applied to the front side electrical pad by the first contacting tip.

E5. The method of any of paragraphs E2-E4, wherein the variable associated with the first probe head region includes at least one of an orientation of the first probe head region with respect to the front side electrical pad, a force applied to the front side electrical pad by the first contacting tip, and a force gradient across a surface of the first probe head region.

E6. The method of any of paragraphs E1-E5, wherein the method further includes adjusting at least one of a planarity and a compliance of the second probe head region based at least in part on a variable associated with the second probe head region.

E7. The method of paragraph E6, wherein adjusting the planarity of the second probe head region includes adjusting an orientation of the second probe head region such that a plane defined by the second probe head region is at least substantially parallel to a plane defined by the test fixture.

E8. The method of any of paragraphs E6-E7, wherein adjusting the compliance of the second probe head region includes adjusting a force that is applied to the auxiliary pad by the second contacting tip.

E9. The method of any of paragraphs E6-E8, wherein the variable associated with the second probe head region includes at least one of an orientation of the second probe head region with respect to the auxiliary pad, a force applied to the auxiliary pad by the second contacting tip, and a force gradient across a surface of the second probe head region.

E10. The method of any of paragraphs E6-E9, wherein adjusting at least one of the planarity and the compliance of the first probe head region is independent from adjusting at least one of the planarity and the compliance of the second probe head region.

E11. The method of any of paragraphs E1-E10, wherein the moving includes at least one of concurrently moving the first probe head region and the second probe head region and concurrently moving the front side electrical pad and the auxiliary pad.

E12. The method of any of paragraphs E1-E11, wherein the method further includes concurrently contacting the first contacting tip with the front side electrical pad and the second contacting tip with the auxiliary pad.

E13. The method of any of paragraphs E1-E12, wherein the first contacting tip is at least substantially similar to the second contacting tip.

E14. The method of any of paragraphs E1-E12, wherein the first contacting tip is different from the second contacting tip.

E15. The method of any of paragraphs E1-E14, wherein the first probe head region includes a plurality of force balance tips configured to apply a force to the device under test, and further wherein the method includes contacting the device under test with the plurality of force balance tips.

E16. The method of any of paragraphs E1-E15, wherein the first probe head region is at least substantially surrounded by the second probe head region.

E17. The method of paragraph E16, wherein the first probe head region and the second probe head region form a concentric structure.

E18. The method of any of paragraphs A1-D17, wherein the electrically probing includes electrically contacting using the method of any of paragraphs E1-E17.

E19. The method of any of paragraphs E1-E18, wherein the method further includes electrically testing the device under test using the method of any of paragraphs D1-D17.

E20. The method of any of paragraphs E1-E19, wherein the device under test includes a plurality of front side electrical pads.

E21. The method of any of paragraphs E1-E20, wherein the device under test includes a plurality of back side electrical pads.

E22. The method of any of paragraphs E1-E21, wherein the auxiliary pad includes a plurality of auxiliary pads.

E23. The method of any of paragraphs E1-E22, wherein the first probe head region includes a plurality of first contacting tips.

E24. The method of any of paragraphs E1-E23, wherein the second probe head region includes a plurality of second contacting tips.

F1. A test fixture for electrically probing a front side and a back side of a device under test, wherein the front side includes a front side electrical pad, and further wherein the back side includes a back side electrical pad, the test fixture comprising:

a receptacle configured to receive the device under test;

an electrical contact configured to contact the back side electrical pad when the device under test is received by the receptacle; and

an auxiliary pad, wherein the auxiliary pad is in electrical communication with the electrical contact, and optionally wherein the auxiliary pad faces in a different direction than the back side electrical pad.

F2. The test fixture of paragraph F1, wherein the front side of the device under test is at least substantially opposed to the back side of the device under test.

F3. The test fixture of any of paragraphs F1-F2, wherein the device under test includes an at least substantially planar device under test, and optionally wherein the device under test is fabricated on a substrate, is operatively attached to a substrate, and/or forms a portion of a substrate.

F4. The test fixture of any of paragraphs F1-F3, wherein the front side forms a first major surface of the device under test, wherein the back side forms a second major surface of the device under test, wherein the device under test includes at least a first minor surface, and further wherein a surface area of the first major surface and the second major surface forms a majority of a surface area of the device under test, optionally wherein the surface area of the first major surface and the second major surface forms at least 50%, at least 60%, at least 70%, at least 80%, at least 90%, at least 95%, at least 97%, at least 98%, at least 99%, at least 99.5%, or at least 99.9% of the surface area of the device under test.

F5. The test fixture of any of paragraphs F1-F4, wherein the device under test includes at least one of an electronic device, a semiconductor device, a transistor, a resistor, a capacitor, an inductor, an electrical conductor, a contact, a via, a through silicon via, a pad, a metal line, an interposer, a processor circuit, a memory circuit, an integrated circuit, an application specific integrated circuit, a logic circuit, a sensor circuit, a system on a chip, a power supply circuit, a space transformer, a microelectronic device, a solar cell, and a power control circuit.

F6. The test fixture of any of paragraphs F1-F5, wherein the device under test includes at least one of a portion of, a layer of, and a precursor to at least one of a stacked semiconductor device, a composite semiconductor device, a 2.5-dimensional integrated circuit, and a 3-dimensional integrated circuit.

F7. The test fixture of any of paragraphs F1-F6, wherein the device under test includes at least one of a substrate, a silicon wafer, a gallium arsenide wafer, a semiconductor wafer, a portion of a semiconductor wafer, a plurality of die, an individual die, die that have not been singulated, a plurality of singulated die on adhesive tape, and a singulated die.

F8. The test fixture of any of paragraphs F1-F7, wherein the device under test includes a thickness of less than 1000 micrometers, optionally including a thickness of less than 500 micrometers, less than 250 micrometers, less than 100 micrometers, less than 90 micrometers, less than 80 micrometers, less than 70 micrometers, less than 60 micrometers, less than 50 micrometers, less than 40 micrometers, less than 30 micrometers, less than 20 micrometers, or less than 10 micrometers, and further optionally wherein the thickness includes an overall thickness of the device under test.

F9. The test fixture of any of paragraphs F1-F8, wherein the device under test includes a plurality of die, wherein each of the plurality of die includes a back side electrical pad, wherein the test fixture includes a plurality of electrical contacts, and further wherein each of the plurality of electrical contacts is configured to contact a respective one of the back side electrical pads.

F10. The test fixture of any of paragraphs F1-F9, wherein the device under test includes a die, and further wherein the die is contained within a die tray that includes the test fixture, optionally wherein the test fixture is configured to be removed from the die tray, and further optionally wherein the die tray includes a plurality of test fixtures.

F11. The test fixture of any of paragraphs F1-F10, wherein the test fixture includes at least one of a socket, a wafer, a semiconductor wafer, a silicon wafer, a carrier wafer, a smart wafer, a translator wafer, a handling wafer, a chuck, a die seat, a tray, and a die tray, and optionally wherein the test fixture includes at least one of an electrical structure, a semiconductor device, a passive electronic component, a resistor, a capacitor, an inductor, an electrical conductor, a via, a through silicon via, a metal line, an interposer, a space transformer, an active electronic component, a transistor, a processor circuit, a memory circuit, an integrated circuit, an application specific integrated circuit, a logic circuit, a sensor circuit, a system on a chip, a power supply circuit, a microelectronic device, a microprocessor, and a power control circuit.

F12. The test fixture of any of paragraphs F1-F11, wherein the test fixture includes an interface region configured to provide an electrical connection between the back side electrical pad and the electrical contact.

F13. The test fixture of paragraph F12, wherein the interface region includes at least one of a conductive material, a polymer, a conductive polymer, an anisotropically conductive polymer, a metal, a conductive grid, a conductive sheet, and a patterned conductive surface, and optionally wherein the interface region includes a compliant layer configured to be compressed.

F14. The test fixture of any of paragraphs F1-F13, wherein the electrical contact includes a test fixture contacting tip configured to contact the back side electrical pad.

F15. The test fixture of any of paragraphs F1-F14, wherein the test fixture includes a test fixture force balance tip configured to apply a force to the device under test.

F16. The test fixture of any of paragraphs F1-F15, wherein the test fixture includes an electrical conduit that provides electrical communication between the electrical contact and the auxiliary pad.

F17. The test fixture of paragraph F16, wherein at least a portion of the electrical conduit is internal to the test fixture.

F18. The test fixture of any of paragraphs F1-F17, wherein the test fixture further includes an alignment structure configured to orient the device under test within a threshold amount of a desired orientation.

F19. The test fixture of paragraph F18, wherein the alignment structure includes a passive alignment structure configured to direct the device under test to the desired orientation, and optionally wherein the passive alignment structure includes a tapered sidewall.

F20. The test fixture of any of paragraphs F18-F19, wherein the alignment structure includes an active alignment structure configured to move the device under test to the desired orientation, and optionally wherein the active alignment structure includes at least one of a stepper motor and a piezoelectric positioner.

F21. The test fixture of any of paragraphs F18-F20, wherein the back side electrical pad includes a characteristic dimension, and further wherein the threshold amount is less than 50% of the characteristic dimension, optionally including less than 40%, less than 30%, less than 25%, less than 20%, less than 15%, less than 10%, less than 5%, less than 4%, less than 3%, less than 2%, or less than 1% of the characteristic dimension.

F22. The test fixture of paragraph F21, wherein the characteristic dimension is less than 250 micrometers, optionally including characteristic dimensions of less than 200 micrometers, less than 150 micrometers, less than 125 micrometers, less than 100 micrometers, less than 90 micrometers, less than 80 micrometers, less than 70 micrometers, less than 60 micrometers, less than 50 micrometers, less than 40 micrometers, less than 30 micrometers, less than 20 micrometers, less than 15 micrometers, less than 10 micrometers, less than 5 micrometers, less than 4 micrometers, less than 3 micrometers, less than 2 micrometers, less than 1 micrometer, less than 0.75 micrometers, less than 0.5 micrometers, less than 0.25 micrometers, or less than 0.1 micrometer.

F23. The test fixture of any of paragraphs F1-F22, wherein the test fixture includes a plurality of electrical contacts.

F24. The test fixture of paragraph F23, wherein at least a portion of the plurality of electrical contacts are in electrical communication with one another, optionally wherein the portion includes selected ones of the plurality of electrical contacts, further optionally wherein the portion includes a majority of the plurality of electrical contacts, and still further optionally wherein the portion includes all of the plurality of electrical contacts.

F25. The test fixture of any of paragraphs F23-F24, wherein the device under test includes a plurality of die including a plurality of back side electrical pads, and further wherein the plurality of electrical contacts are configured to electrically connect selected ones of the plurality of back side electrical pads of a first die of the plurality of die together with selected ones of the plurality of back side electrical pads of a second die of the plurality of die.

F26. The test fixture of any of paragraphs F23-F25, wherein the auxiliary pad includes a plurality of auxiliary pads, and further wherein the plurality of auxiliary pads are configured to be in electrical communication with the plurality of electrical contacts.

F27. The test fixture of paragraph F26, wherein each of the plurality of auxiliary pads is configured to be in electrical communication with a selected one of the plurality of electrical contacts.

F28. The test fixture of any of paragraphs F26-F27, wherein each of the plurality of auxiliary pads is configured to be in electrical communication with a plurality of electrical contacts.

F29. The test fixture of any of paragraphs F26-F28, wherein a portion of the plurality of auxiliary pads is configured to be in electrical communication with a selected one of the electrical contacts.

F30. The test fixture of any of paragraphs F23-F29, wherein the plurality of electrical contacts are configured in complementary locations to a corresponding location of at least a portion of the plurality of back side electrical pads.

F31. The test fixture of paragraph F30, wherein the plurality of electrical contacts are configured in a periodic array, and optionally wherein a pitch of the periodic array is less than a characteristic dimension of the back side electrical pads, optionally wherein the pitch of the periodic array is less than 50% of the characteristic dimension of the back side electrical pads, and further optionally wherein the pitch of the periodic array is less than 40%, less than 30%, less than 25%, less than 20%, less than 15%, or less than 10% of the characteristic dimension of the back side electrical pads.

F32. The test fixture of any of paragraphs F1-F31, wherein the auxiliary pad is configured to form an electrical connection with a probe head, and optionally wherein the auxiliary pad and the front side pad are configured to form an electrical connection with the probe head.

F33. The test fixture of any of paragraphs F1-F32, wherein the auxiliary pad includes an auxiliary pad electrical contact, and further wherein the auxiliary pad electrical contact is configured to form an electrical connection with the device under test.

F34. The test fixture of any of paragraphs F1-F33, wherein at least one of the front side electrical pad, the back side electrical pad, and the auxiliary pad includes an at least substantially flat contacting surface, and optionally wherein the front side electrical pad, the back side electrical pad, and the auxiliary pad include an at least substantially flat contacting surface.

F35. The test fixture of any of paragraphs F1-F34, wherein at least one of the front side electrical pad and the back side electrical pad includes at least one of a bond pad, a contact pad, and a landing pad.

F36. The test fixture of any of paragraphs F1-F35, wherein the front side electrical pad defines a front side surface normal, the back side electrical pad defines a back side surface normal, and the auxiliary pad defines an auxiliary pad surface normal, and further wherein the back side surface normal is in a different direction from at least one of the front side surface normal and the auxiliary pad surface normal, and optionally wherein the back side surface normal is generally opposed to at least one of the front side surface normal and the auxiliary pad surface normal.

F37. The test fixture of paragraph F36, wherein the front side surface normal is in an at least substantially similar direction, and optionally in the same direction, as the auxiliary pad surface normal.

F38. The test fixture of any of paragraphs F1-F37, wherein the front side electrical pad faces in a front side direction, wherein the back side electrical pad faces in a back side direction, and further wherein the auxiliary pad faces in an auxiliary pad direction.

F39. The test fixture of paragraph F38, wherein the auxiliary pad direction is at least substantially the same as the front side direction.

F40. The test fixture of any of paragraphs F38-F39, wherein the auxiliary pad direction is different from the back side direction.

F41. The test fixture of paragraph F40, wherein the auxiliary pad direction is within a threshold angle of the front side direction, and optionally wherein the threshold angle is less than 90 degrees, less than 80 degrees, less than 70 degrees, less than 60 degrees, less than 50 degrees, less than 40 degrees, less than 30 degrees, less than 20 degrees, less than 15 degrees, less than 10 degrees, less than 5 degrees, less than 4 degrees, less than 3 degrees, less than 2 degrees, or less than 1 degree.

F42. The test fixture of any of paragraphs F1-F41, wherein the test fixture further includes a thermal management structure configured to control a temperature of at least one of the test fixture and the device under test, and optionally wherein the thermal management structure is configured to at least one of maintain the temperature near a target temperature and maintain the temperature between predetermined upper and lower threshold temperatures.

F43. The test fixture of any of paragraphs F1-F42, wherein the electrical contact includes a first electrical contact, wherein the auxiliary pad includes a first auxiliary pad, wherein the test fixture further includes a second electrical contact and a second auxiliary pad, and further wherein the test fixture includes a switching structure configured to selectively provide electrical communication between at least two of the first electrical contact and the first auxiliary pad, the first electrical contact and the second auxiliary pad, the second electrical contact and the first auxiliary pad, and the second electrical contact and the second auxiliary pad.

G1. A probe head configured to electrically contact a front side electrical pad and an auxiliary pad, wherein the auxiliary pad is located on a test fixture, wherein the front side electrical pad is located on a front side of a device under test that is received in the test fixture, and further wherein the auxiliary pad is in electrical communication with a back side electrical pad located on a back side of the device under test, the probe head comprising:

a first probe head region including a first contacting tip configured to contact the front side electrical pad; and

a second probe head region including a second contacting tip configured to contact the auxiliary pad.

G2. The probe head of paragraph G1, wherein the probe head is configured to adjust a contacting parameter of the second probe head region independent of a contacting parameter of the first probe head region.

G3. The probe head of paragraph G2, wherein the contacting parameter of the first probe head region includes at least one of a planarity of the first probe head region and a compliance of the first probe head region.

G4. The probe head of paragraph G3, wherein, when electrically contacting the front side electrical pad, the probe head is configured to adjust the planarity of the first probe head region by adjusting an orientation of the first probe head region such that a plane defined by the first probe head region is at least substantially parallel to a plane defined by the front side of the device under test.

G5. The probe head of any of paragraphs G3-G4, wherein, when electrically contacting the front side electrical pad, the probe head is configured to adjust the compliance of the first probe head region by adjusting a force that is applied to the front side electrical pad by the first contacting tip.

G6. The probe head of any of paragraphs G2-G5, wherein the contacting parameter of the second probe head region includes at least one of a planarity of the second probe head region and a compliance of the second probe head region.

G7. The probe head of paragraph G6, wherein, when electrically contacting the auxiliary pad, the probe head is configured to adjust the planarity of the second probe head region by adjusting an orientation of the second probe head region such that a plane defined by the second probe head region is at least substantially parallel to a plane defined by the test fixture.

G8. The probe head of any of paragraphs G6-G7, wherein, when electrically contacting the auxiliary pad, the probe head is configured to adjust the compliance of the second probe head region by adjusting a force that is applied to the auxiliary pad by the second contacting tip.

G9. The probe head of any of paragraphs G1-G8, wherein the first contacting tip is at least substantially the same as the second contacting tip.

G10. The probe head of any of paragraphs G1-G8, wherein the first contacting tip is different from the second contacting tip.

G11. The probe head of any of paragraphs G1-G10, wherein the probe head further includes a plurality of force balance tips configured to apply a force to the device under test.

G12. The probe head of any of paragraphs G1-G11, wherein the first probe head region is at least substantially surrounded by the second probe head region.

G13. The probe head of paragraph G12, wherein the first probe head region and the second probe head region form a concentric structure.

G14. The probe head of any of paragraphs G1-G13, wherein the probe head is configured to supply a test signal to the device under test, and optionally wherein the probe head is configured to supply the test signal to at least one of the front side electrical pad and the auxiliary pad.

G15. The probe head of paragraph G14, wherein the probe head is configured to receive the test signal from at least one of a probe system, a function generation, and a spectrum analyzer.

G16. The probe head of any of paragraphs G14-G15, wherein the test signal includes at least one of a DC test signal, an AC test signal, a radio frequency test signal, and a microwave frequency test signal.

G17. The probe head of any of paragraphs G1-G16, wherein the probe head is configured to receive a resultant signal from the device under test, and optionally wherein the probe head is configured to receive the resultant signal from at least one of the front side electrical pad and the auxiliary pad.

G18. The probe head of paragraph G17, wherein the probe head is configured to supply the resultant signal to at least one of a probe system and a spectrum analyzer.

G19. The probe head of any of paragraphs G17-G18, wherein the resultant signal includes at least one of a DC resultant signal, an AC resultant signal, a radio frequency resultant signal, a microwave frequency resultant signal, and a null resultant signal.

G20. The probe head of any of paragraphs G17-G19, wherein the device under test is configured to conduct the test signal between the front side electrical pad and the back side electrical pad to produce the resultant signal.

G21. The probe head of any of paragraphs G1-G20, wherein the first probe head region includes a plurality of first contacting tips.

G22. The probe head of any of paragraphs G1-G21, wherein the second probe head region includes a plurality of second contacting tips.

G23. The probe head of any of paragraphs G1-G22, wherein the device under test includes a plurality of front side electrical pads.

G24. The probe head of any of paragraphs G1-G23, wherein the device under test includes a plurality of back side electrical pads

G25. The probe head of any of paragraphs G1-G24, wherein the test fixture includes a plurality of auxiliary pads.

G26. The probe head of any of paragraphs G1-G25, wherein the probe head further includes a thermal management structure configured to control a temperature of at least one of the probe head and the device under test, and optionally wherein the thermal management structure is configured to at least one of maintain the temperature near a target temperature and maintain the temperature between predetermined upper and lower threshold temperatures.

H1. A test system configured to electrically test two sides of a device under test, wherein the device under test includes a front side facing in a front side direction and a back side facing in a back side direction, wherein the front side includes a plurality of front side electrical pads, and further wherein the back side includes a plurality of back side electrical pads, and optionally wherein the front side direction is at least substantially opposed to the back side direction, the test system comprising:

a test fixture, wherein the test fixture is configured to provide electrical communication between at least a portion of the back side electrical pads and a plurality of auxiliary pads, wherein the back side electrical pads face in the back side direction, and further wherein the auxiliary pads face in the front side direction; and

a probe head configured to electrically contact at least a portion of the plurality of front side electrical pads and at least a portion of the plurality of auxiliary pads.

H2. The test system of paragraph H1, wherein the test fixture includes the test fixture of any of paragraphs F1-F43.

H3. The test system of any of paragraphs H1-H2, wherein the probe head includes the probe head of any of paragraphs G1-G26.

H4. The test system of any of paragraphs H1-H3, wherein the test system is configured to electrically test the device under test for at least one of continuity, open circuits, and short circuits between at least one of the plurality of front side electrical pads and at least one of the plurality of back side electrical pads.

H5. The test system of any of paragraphs H1-H4, wherein the test system further includes a signal generator configured to provide a test signal to the device under test, optionally wherein the test signal includes at least one of a DC test signal, an AC test signal, and a radio frequency test signal, and further optionally wherein the signal generator includes at least one of a probe system, a function generator, and a spectrum analyzer.

H6. The test system of any of paragraphs H1-H5, wherein the test system further includes a signal analyzer configured to receive a resultant signal from the device under test, and optionally wherein the signal analyzer includes at least one of a probe system and a spectrum analyzer.

H7. The test system of any of paragraphs H1-H5, wherein the test system further includes a thermal management structure configured to control a temperature of a portion of the test system, optionally wherein the portion of the test system includes at least one of the probe head, the test fixture, and the device under test, and further optionally wherein the thermal management structure is configured to at least one of maintain the temperature near a target temperature and maintain the temperature between predetermined upper and lower threshold temperatures.

I1. The use of any of the methods of any of paragraphs A1-E24 with any of the test fixtures of any of paragraphs F1-F43, any of the probe heads of any of paragraphs G1-G26, and/or any of the test systems of any of paragraphs H1-H7.

I2. The use of any of the test fixtures of any of paragraphs F1-F43, any of the probe heads of any of paragraphs G1-G26, and/or any of the test systems of any of paragraphs H1-H7 with any of the methods of any of paragraphs A1-E24.

I3. The use of any of the methods of any of paragraphs A1-E24, any of the test fixtures of any of paragraphs F1-F43, any of the probe heads of any of paragraphs G1-G26, and/or any of the test systems of any of paragraphs H1-H7 to form an electrical connection with a device under test.

I4. The use of any of the methods of any of paragraphs A1-E24, any of the test fixtures of any of paragraphs F1-F43, any of the probe heads of any of paragraphs G1-G26, and/or any of the test systems of any of paragraphs H1-H7 to electrically test a device under test.

I5. The use of a test fixture to route a back side electrical pad of a device under test to an auxiliary pad that faces in at least substantially the same direction as a front side electrical pad of the device under test.

I6. The use of a probe head to electrically contact, and optionally to simultaneously contact, a plurality of front side electrical contacts of a device under test and a plurality of auxiliary pads that are in electrical communication with a plurality of back side electrical contacts of the device under test.

J1. Any of paragraphs A1-16, wherein the word “electrical” is instead the word “optical,” wherein the word “electronic” is instead the word “optical,” and further wherein the word “electrically” is instead the word “optically.”

J2. Any of paragraphs A1-16, wherein the word “electrical” is instead the word “wireless,” wherein the word “electronic” is instead the word “wireless,” and further wherein the word “electrically” is instead the word “wirelessly.”

### INDUSTRIAL APPLICABILITY

The systems and methods disclosed herein are applicable to the electronic device test, assembly, and manufacturing industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A method of electrically probing a front side and an opposed back side of a device under test, wherein the front side includes a front side electrical pad, and further wherein the back side includes a back side electrical pad, the method comprising:
forming an electrical connection between the back side electrical pad and an auxiliary pad that faces in a different direction than the back side electrical pad; and
electrically contacting the front side electrical pad and the auxiliary pad with a contacting structure by decreasing a distance between the contacting structure and the front side of the device under test.

2. The method of claim 1, wherein the electrically contacting includes contacting the auxiliary pad and the front side electrical pad with a probe head that includes the contacting structure.

3. The method of claim 2, wherein the method includes moving the probe head and the front side electrical pad into contact with each other and moving the probe head and the auxiliary pad into contact with each other.

4. The method of claim 3, wherein the moving includes simultaneously contacting both the front side electrical pad and the auxiliary pad with the probe head during the moving.

5. The method of claim 1, wherein the electrically contacting includes electrically contacting the front side electrical pad and the auxiliary pad with a single probe head, wherein the single probe head includes a first contacting tip and a second contacting tip.

6. The method of claim 5, wherein the first contacting tip and the second contacting tip face in at least substantially the same direction, and further wherein the electrically contacting includes electrically contacting the front side electrical pad with the first contacting tip and electrically contacting the auxiliary pad with the second contacting tip.

7. The method of claim 1, wherein the forming an electrical connection between the back side electrical pad and the auxiliary pad includes placing the device under test in a test fixture configured to provide the electrical connection between the back side electrical pad and the auxiliary pad, wherein the auxiliary pad forms a portion of the test fixture.

8. The method of claim 1, wherein the back side includes a plurality of back side electrical pads, and further wherein the forming an electrical connection includes electrically connecting selected ones of the plurality of back side electrical pads together.

9. The method of claim 1, wherein the back side includes a plurality of back side electrical pads, wherein the device under test includes a plurality of die, and further wherein the forming and electrical connection includes electrically connecting selected ones of the plurality of back side electrical pads of a first die of the plurality of die together with selected ones of the plurality of back side electrical pads of a second die of the plurality of die.

10. The method of claim 1, wherein the back side includes a plurality of back side electrical pads, wherein the auxiliary pad includes a plurality of auxiliary pads, and further wherein the forming an electrical connection includes forming an electrical connection between selected ones of the plurality of back side electrical pads and selected ones of the plurality of auxiliary pads.

11. The method of claim 10, wherein the method further includes receiving the device under test in a test fixture that includes a plurality of electrical contacts configured to align with the plurality of back side electrical pads, and further wherein the forming an electrical connection includes forming the electrical connection between the plurality of electrical contacts and the plurality of back side electrical pads.

12. The method of claim 11, wherein the plurality of electrical contacts are configured in a periodic array, wherein a pitch of the periodic array is less than an average spacing between the plurality of back side electrical pads, and further wherein the method includes electrically mapping a location of at least a portion of the plurality of back side electrical pads by supplying a test signal to at least a portion of the plurality of back side electrical pads and receiving a resultant signal from the device under test.

13. The method of claim 1, wherein the device under test includes a plurality of die, wherein each of the plurality of die includes a back side electrical pad and a front side electrical pad, wherein the auxiliary pad includes a plurality of auxiliary pads, wherein the forming includes forming the electrical connection between the plurality of auxiliary pads and respective back side electrical pads of the plurality of die, and further wherein the electrically contacting includes electrically contacting the front side electrical pad of each of the plurality of die and the plurality of auxiliary pads.

14. The method of claim 13, wherein the method further includes providing a test signal to each of the plurality of die at least one of simultaneously and sequentially.

15. The method of claim 13, wherein the method further includes providing a test signal to a first die of the plurality of die and receiving a resultant signal from a second die of the plurality of die.

16. The method of claim 1, wherein the device under test includes a die, wherein the die is contained within a die tray that includes a test fixture, wherein the forming an electrical connection includes forming an electrical connection between the back side electrical pad and the test fixture, and further wherein the electrically contacting includes electrically contacting a front side of the die and a front side of at least one of the die tray and the test fixture.

17. A method of electrically testing a device under test, wherein the device under test includes a front side including a front side electrical pad and a back side including a back side electrical pad, the method comprising:
electrically probing the front side electrical pad of the device under test and the back side electrical pad of the device under test using the method of claim 1; and
supplying a test signal to at least one of the front side electrical pad and the back side electrical pad.

18. The method of claim 17, wherein the method further includes receiving a resultant signal from the other of the front side electrical pad and the back side electrical pad.

19. A test fixture for electrically probing a front side and an opposed back side of a device under test, wherein the front side includes a front side electrical pad, and further wherein the back side includes a back side electrical pad, the test fixture comprising:
a receptacle configured to receive the device under test;
an electrical contact configured to contact the back side electrical pad when the device under test is received by the receptacle; and
an auxiliary pad, wherein the auxiliary pad is in electrical communication with the electrical contact and faces in a different direction than the back side electrical pad.

20. The test fixture of claim 19, wherein the test fixture includes a plurality of electrical contacts, wherein the device under test includes a plurality of die including a plurality of back side electrical pads, and further wherein the plurality of electrical contacts are configured to electrically connect selected ones of the plurality of back side electrical pads of a first die of the plurality of die together with selected ones of the plurality of back side electrical pads of a second die of the plurality of die.

21. The test fixture of claim 19, wherein the electrical contact and the auxiliary pad face in substantially the same direction.

22. The test fixture of claim 19, wherein the electrical contact is a first electrical contact, wherein the auxiliary pad is a first auxiliary pad, wherein the test fixture further includes a second electrical contact and a second auxiliary pad, and further wherein the test fixture includes a switching structure configured to selectively provide electrical communication between at least two of the first electrical contact and the first auxiliary pad, the first electrical contact and the second auxiliary pad, the second electrical contact and the first auxiliary pad, and the second electrical contact and the second auxiliary pad.

23. A test system configured to electrically test two opposed sides of a device under test, wherein the device under test includes a front side facing in a front side direction and a back side facing in a back side direction that is opposed to the front side direction, wherein the front side includes a plurality of front side electrical pads, and further wherein the back side includes a plurality of back side electrical pads, the test system comprising:
the test fixture of claim 19, wherein the test fixture includes a plurality of electrical contacts and a plurality of auxiliary pads that are in electrical communication with the plurality of electrical contacts, wherein the plurality of electrical contacts is configured to electrically contact the plurality of back side electrical pads and to provide electrical communication between the plurality of back side electrical pads and the plurality of auxiliary pads, wherein the plurality of back side electrical pads face in the back side direction, and further wherein the plurality of auxiliary pads face in the front side direction; and
a probe head configured to electrically contact at least a portion of the plurality of front side electrical pads and at least a portion of the plurality of auxiliary pads.

24. The test system of claim 23, wherein the test system further includes a signal generator that provides a test signal to the device under test and a signal analyzer that receives a resultant signal from the device under test.
